(19) United States
(12) Patent Application Publication
(10) Pub. No.: US 2025/0248161 A1
(43) Pub. Date: Jul. 31, 2025

(54) IMAGE SENSOR AND SEMICONDUCTOR DEVICE INCLUDING THROUGH VIA

(71) Applicant: SAMSUNG ELECTRONICS CO., LTD., Suwon-si (KR)

(72) Inventors: Doowon KWON, Suwon-si (KR); Doyeon KIM, Suwon-si (KR); Seungjae OH, Suwon-si (KR); Minho JANG, Suwon-si (KR)

(73) Assignee: SAMSUNG ELECTRONICS CO., LTD., Suwon-si (KR)

(21) Appl. No.: 18/897,991

(22) Filed: Sep. 26, 2024

(30) Foreign Application Priority Data
Jan. 30, 2024 (KR) 10-2024-0013869

(51) Int. Cl. H01L 27/146

(52) U.S. Cl. CPC H10F 39/811; H10F 39/809

(57) ABSTRACT

An image sensor includes a first semiconductor chip including a first substrate, a first interlayer insulating layer covering the first substrate, and first wirings and a first landing wiring disposed in the first interlayer insulating layer, a first through via penetrating the first substrate and contacting the first landing wiring, and at least one first mark pattern disposed in the first landing wiring and overlapping the first through via.

### CROSS-REFERENCE TO RELATED APPLICATIONS

This U.S. non-provisional patent application claims priority under 35 U.S.C. § 119 to Korean Patent Application No.10-2024-0013869 filed on Jan. 30, 2024, in the Korean Intellectual Property Office, the entire contents of which are hereby incorporated by reference.

### BACKGROUND OF THE INVENTION

The present disclosure relates to an image sensor and a semiconductor device, and more particularly, relates to an image sensor and a semiconductor device including a through via.

An image sensor is a semiconductor device to transform optical images into electrical signals. The image sensor may be classified into a charge coupled device (CCD) type or a complementary metal oxide semiconductor (CMOS) type. A CIS (CMOS image sensor) refers to a CMOS type image sensor. The CIS may include a plurality of two-dimensionally arranged pixels. Each of the pixels includes a photodiode (PD). The photodiode serves to transform an incident light into an electrical signal.

### SUMMARY

One or more embodiments of the present disclosure provide to an image sensor with improved reliability.

Further, one or more embodiments of the present disclosure provide to a semiconductor device with improved reliability.

The problem to be solved by the present disclosure is not limited to the problems mentioned above, and other problems not mentioned will be clearly understood by those skilled in the art from the description below.

An image sensor may include a first semiconductor chip including a first substrate; a first interlayer insulating layer covering the first substrate; and first wirings and a first landing wiring disposed in the first interlayer insulating layer; a first through via penetrating the first substrate and contacting the first landing wiring; and at least one first mark pattern disposed in the first landing wiring and overlapping the first through via.

An image sensor may include: a first semiconductor chip including a first substrate, a first interlayer insulating layer covering the first substrate, and first wirings and a first landing wiring disposed in the first interlayer insulating layer; a second semiconductor chip disposed on the first semiconductor chip and including: a second substrate including a plurality of light-receiving regions; a second interlayer insulating layer covering the second substrate; and second wirings disposed in the second interlayer insulating layer; and a first through via penetrating the first substrate and contacting the first landing wiring, wherein the first landing wiring may include a pad portion in contact with the first through via, wherein the pad portion has a cross shape or line shape when viewed in a plan view, and wherein the first through via covers both an upper surface and a side surface of the pad portion.

A semiconductor device may include: a first semiconductor chip including a first substrate, a first interlayer insulating layer covering the first substrate, and first wirings and a first landing wiring disposed in the first interlayer insulating layer; a first through via penetrating the first substrate and contacting the first landing wiring; and at least one first mark pattern disposed in the first landing wiring and overlapping the first through via.

An image sensor may include: a first semiconductor chip including logic circuits; a second semiconductor chip stacked on the first semiconductor chip and including photoelectric converters to convert light to electric signals; a through via penetrating a substrate of the first semiconductor chip to provide an interconnection between the first semiconductor chip and the second semiconductor chip, and inserted into a through via hole formed within a landing wiring of the first semiconductor chip to contact an inner sidewall of the landing wiring; and a mark pattern disposed in the landing wiring and in contact with the through via.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a block diagram for explaining an image sensor according to embodiments of the present disclosure.

FIG. 2 is a circuit diagram of an image sensor according to embodiments of the present disclosure.

FIG. 3 is a schematic exploded perspective view of an image sensor according to embodiments of the present disclosure.

FIG. 4 is a cross-sectional view taken along line A-A′ of the image sensor of FIG. 3 according to embodiments of the present disclosure.

FIG. 5A is an enlarged view of portion ‘P1’ of FIG. 4 according to embodiments of the present disclosure.

FIG. 5B is a plan view showing a portion of FIG. 5A.

FIGS. 6A to 6C are enlarged views of portion ‘P1’ of FIG. 4 according to embodiments of the present disclosure.

FIG. 7A is an enlarged view of portion ‘P1’ of FIG. 4 according to embodiments of the present disclosure.

FIG. 7B is a plan view showing a portion of FIG. 7A.

FIG. 8A is an enlarged view of portion ‘P1’ of FIG. 4 according to embodiments of the present disclosure.

FIG. 8B is a plan view showing a portion of FIG. 8A.

FIG. 9A is an enlarged view of portion ‘P1’ of FIG. 4 according to embodiments of the present disclosure.

FIG. 9B is a plan view showing a portion of FIG. 9A.

FIGS. 10A to 10J are cross-sectional views showing a manufacturing process of the image sensor having the cross-section of FIG. 4.

FIG. 11 is a cross-sectional view taken along line A-A′ of the image sensor of FIG. 3 according to embodiments of the present disclosure.

FIG. 12 is a cross-sectional view taken along line A-A′ of the image sensor of FIG. 3 according to embodiments of the present disclosure.

FIGS. 13A to 13H are cross-sectional views sequentially showing a process of manufacturing the image sensor of FIG. 12.

FIG. 14 is a cross-sectional view of a semiconductor memory device according to embodiments of the present disclosure.

FIG. 15 is an enlarged view of portion ‘P4’ of FIG. 14.

FIG. 16 is a cross-sectional view of a semiconductor memory device according to embodiments of the present disclosure.

### DETAILED DESCRIPTION

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

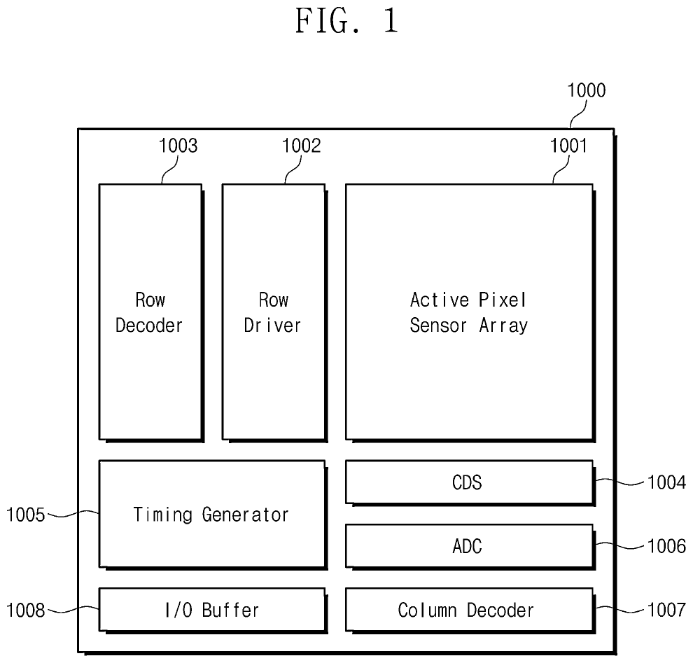

FIG. 1 is a block diagram for explaining an image sensor according to embodiments of the present disclosure.

Referring to FIG. 1, an image sensor 1000 may receive a light from an outside source and may generate a digital signal. An electronic device including the image sensor 1000 may display an image in a display panel based on the digital signal. For example, an electronic device that includes an image sensor may be implemented with one of various types of electronic devices such as a smartphone, a tablet personal computer (PC), a laptop PC, and a wearable device.

The image sensor 1000 may include an active pixel sensor array 1001, a row driver 1002, a row decoder 1003, a column decoder 1007, a timing generator 1005, a correlated double sampler (CDS) 1004, an analog-to-digital converter (ADC) 1006, and an input/output (I/O) buffer 1008.

The active pixel sensor array 1001 may include a plurality of unit pixels that are two-dimensionally arranged and may convert optical signals into electrical signals. The active pixel sensor array 1001 may be driven by a plurality of driving signals (e.g., a pixel selection signal, a reset signal, and a charge transfer signal) provided from the row driver 1002. In addition, the converted electrical signals may be provided to the correlated double sampler 1004

The row driver 1002 may provide a plurality of driving signals for driving a plurality of the unit pixels to the active pixel sensor array 1001 based on signals decoded in the row decoder 1003. When the unit pixels are arranged in a matrix form, the driving signals may be provided in the unit of row of the matrix.

The timing generator 1005 may provide timing signals and control signals to the row decoder 1003 and the column decoder 1007.

The correlated double sampler 1004 may receive electrical signals generated from the active pixel sensor array 1001 and may hold and sample the received electrical signals. The correlated double sampler 1004 may perform correlated double sampling to sample both a specific noise level and a signal level of the electrical signal and may output a difference level corresponding to a difference between the noise level and the signal level.

The analog-to-digital converter 1006 may convert an analog signal, which corresponds to the difference level outputted from the correlated double sampler 1004, into a digital signal and may output the digital signal.

The I/O buffer 1008 may latch the digital signals and may sequentially output the latched digital signals to an image signal processor based on signals decoded in the column decoder 1007.

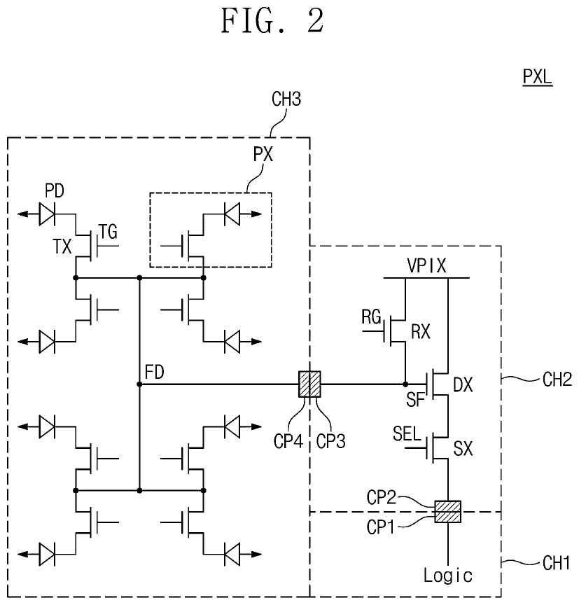

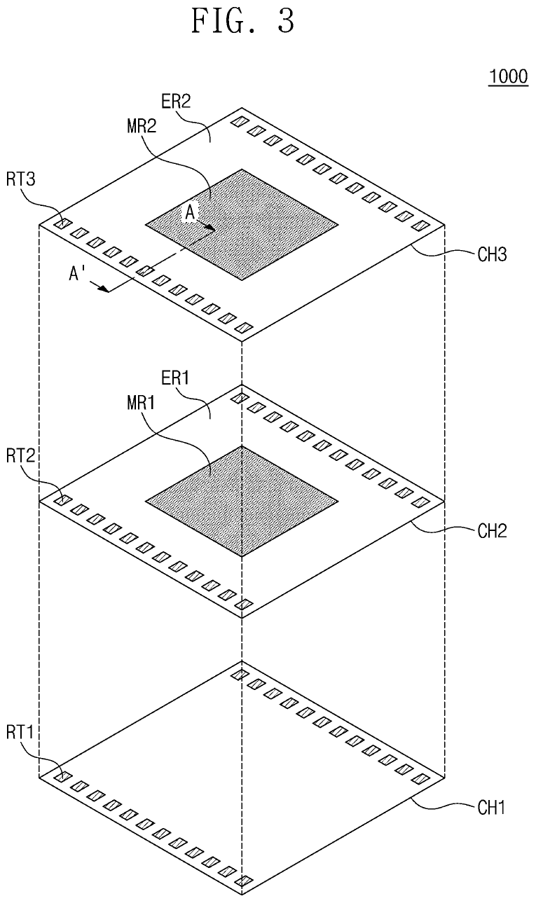

FIG. 2 is a circuit diagram of an image sensor according to embodiments of the present disclosure. FIG. 3 is a schematic exploded perspective view of an image sensor according to embodiments of the present disclosure.

Referring to FIGS. 2 and 3, the image sensor 1000 according to embodiments of the present disclosure may include a three-dimensional (3D) integrated circuit (IC) structure in which a plurality of semiconductor chips (e.g., first to third semiconductor chips CH1, CH2, and CH3) are sequentially stacked to be placed on top of each other in a vertical stack. Through via regions RT1, RT2, and RT3 may be disposed at edges of the first to third semiconductor chips CH1, CH2, and CH3, respectively, to allow vertical interconnections between the stacked semiconductor chips CH1, CH2, and CH3. Through vias may be disposed in the through via regions RT1, RT2, and RT3.

Logic circuits may be disposed on the first semiconductor chip CH1. The logic circuits may include the row driver 1002, the row decoder 1003, the column decoder 1007, the timing generator 1005, the correlated double sampler (CDS) 1004, the analog-to-digital converter (ADC) 1006, and the input/output buffer (I/O buffer) 1008 of FIG. 1. The first semiconductor chip CH1 may be connected to the second semiconductor chip CH2 through a first bonding pad CP1.

Referring to FIGS. 2 and 3, a pixel (or a pixel group) PXL may include a plurality of transfer transistors TX, a plurality of photoelectric converters PD, a plurality of floating diffusion regions, at least one reset transistor RX, at least one source follower transistor DX, and at least one selection transistor SX. A plurality of pixels (or pixel groups) PXL may be disposed in both the second semiconductor chip CH2 and the third semiconductor chip CH3. In detail, the second semiconductor chip CH2 includes a first main region MR1 and a first edge region ER1 surrounding the first main region MR1. A plurality of reset transistors RX, source follower transistors DX, and selection transistors SX shown in FIG. 2 may be provided in an array form in the first main region MR1. The reset transistor RX includes a reset gate RG. A pixel voltage VPIX may be applied to one terminal of the reset transistor RX. The other terminal of the reset transistor RX may be connected to a third bonding pad CP3. The source follower transistor DX includes a source follower gate SF. The source follower gate SF may be connected to the third bonding pad CP3. A pixel voltage VPIX may be applied to one terminal of the source follower transistor DX. The other terminal of the source follower transistor DX is connected to one terminal of the selection transistor SX. The selection transistor SX includes a selection gate SEL. The other terminal of the selection transistor SX may be connected to a second bonding pad CP2. The second bonding pad CP2 of the second semiconductor chip CH2 may be in contact with the first bonding pad CP1 of the first semiconductor chip CH1. The third bonding pad CP3 and the second bonding pad CP2 may be provided in the plural and may be disposed in the first main region MR1.

A second main region MR2 and a second edge region ER2 are disposed on the third semiconductor chip CH3. A plurality of light-receiving regions PX are two-dimensionally arranged in the second main region MR2. A photoelectric converter PD and a transfer transistor TX are disposed in/on each light-receiving region PX. The transfer transistor TX may include a transfer gate TG. One terminal of the transfer transistor TX may be connected to each photoelectric converter PD, and the other terminal of the transfer transistor TX may be a floating diffusion region FD. The floating diffusion regions FD of the light-receiving regions PX may be connected to each other or may be shared with each other. At least one floating diffusion region FD is connected to a fourth bonding pad CP4. The fourth bonding pad CP4 of the third semiconductor chip CH3 may be in contact with the third bonding pad CP3 of the second semiconductor chip CH2. One reset transistor RX, one source follower transistor DX, and one selection transistor SX disposed on the second semiconductor chip CH2 may be connected to a plurality of transfer transistors TX.

The first main region MR1 of the second semiconductor chip CH2 and the second main region MR2 of the third semiconductor chip CH3 may constitute the active pixel sensor array 1001 of FIG. 1.

The photoelectric converter PD of the third semiconductor chip CH3 may generate and accumulate photocharges in proportion to the amount of light incident from the outside. The photoelectric converter PD may include a photo diode, a photo transistor, a photo gate, a pinned photo diode, or a combination thereof. The transfer transistor TX may transmit the charge generated in the photoelectric converter PD to the floating diffusion region FD. The floating diffusion region FD may receive charges generated in the photoelectric converter PD and store the charges cumulatively. The source follower transistor DX may be controlled depending on the amount of photocharges accumulated in the floating diffusion region FD.

The reset transistor RX may periodically reset the charges accumulated in the floating diffusion region FD. A drain electrode of the reset transistor RX may be connected to the floating diffusion region FD, and a source electrode may be connected to a power supply voltage. When the reset transistor RX is turned on, the power supply voltage connected to the source electrode of the reset transistor RX may be applied to the floating diffusion region FD. Accordingly, when the reset transistor RX is turned on, the charges accumulated in the floating diffusion region FD may be discharged and the floating diffusion region FD may be reset.

The source follower transistor DX including the source follower gate electrode SF may serve as a source follower buffer amplifier. The source follower transistor DX may amplify the potential change in the floating diffusion region FD and output the amplified potential change to the output line of the logic circuit.

The selection transistor SX including the selection gate electrode SEL may select a pixel PXL to be read row by row. When the selection transistor SX is turned on, the power supply voltage may be applied to a drain electrode of the source follower transistor DX.

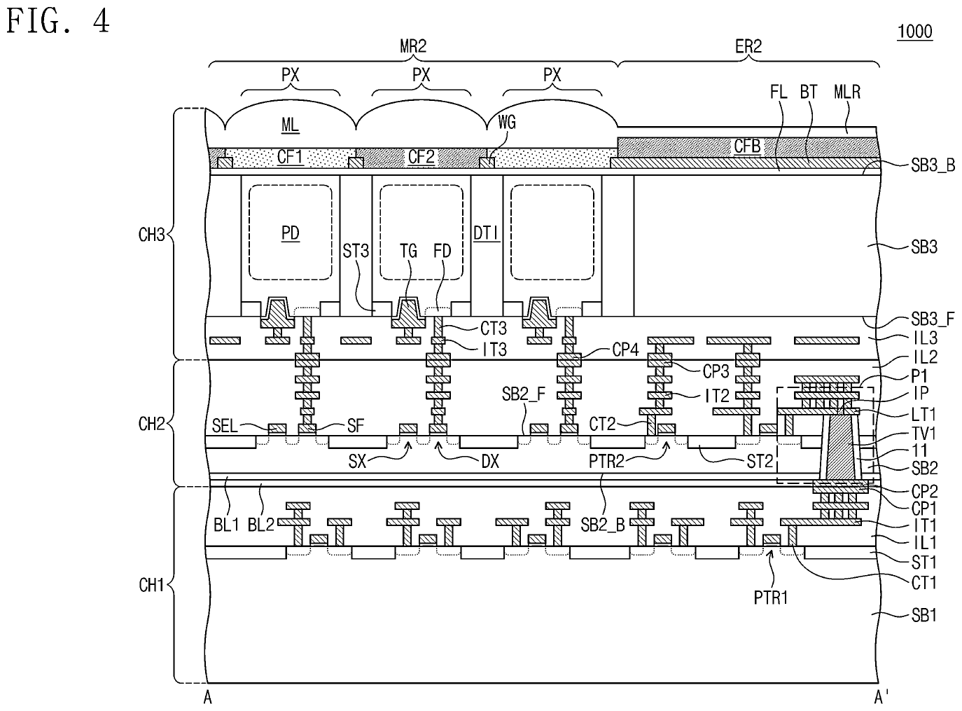

FIG. 4 is a cross-sectional view of the image sensor of FIG. 3 taken along line A-A′ according to embodiments of the present disclosure.

Referring to FIG. 4, an image sensor 1000 includes first to third semiconductor chips CH1, CH2, and CH3 sequentially stacked. The first semiconductor chip CH1 may be a logic circuit chip. The first semiconductor chip CH1 includes a first substrate SB1, first device isolation portions ST1, first peripheral transistors PTR1, first contact plugs CT1, and first wirings IT1, a first interlayer insulating layer IL1, and a first bonding pad CP1. The first device isolation portions ST1 may be disposed on a front surface of the first substrate SB1 to define active regions for the first peripheral transistors PTR1. First peripheral transistors PTR1, first contact plugs CT1, and first wirings IT1 may be disposed on the front surface of the first substrate SB1, and the first interlayer insulating layer IL1 may cover the front surface of the first substrate SB1. The first substrate SB1 may be, for example, a silicon single crystal wafer, a silicon epitaxial layer, or a silicon on insulator (SOI) substrate. The first interlayer insulating layer IL1 may have a single-layer or multi-layer structure of at least one of silicon oxide, silicon nitride, silicon oxynitride, and porous insulator.

The first peripheral transistors PTR1, first contact plugs CT1, and first wirings IT1 may form logic circuits. The logic circuits may include the row driver 1002, the row decoder 1003, the column decoder 1007, the timing generator 1005, the correlated double sampler (CDS) 1004, the analog-to-digital converter (ADC) 1006, and the input/output buffer (I/O buffer) 1008 of FIG. 1.

The second semiconductor chip CH2 may transmit charges or electrical signals generated by light in the light-receiving regions PX of the third semiconductor chip CH3 to the first semiconductor chip CH1. The second semiconductor chip CH2 includes first and second lower insulating layers BL1 and BL2, a second substrate SB2, a second device isolation portion ST2, a source follower transistor DX, and a selection transistor SX, second peripheral transistors PTR2, second contact plugs CT2, second wirings IT2, a first landing wiring LT1, a second interlayer insulating layer IL2, a second bonding pad CP2, a third bonding pad CP3, a first through via TV1, and a first via insulating layer 11.

The second substrate SB2 may be, for example, a silicon single crystal wafer, a silicon epitaxial layer, or a silicon on insulator (SOI) substrate. Each of the first and second lower insulating layers BL1 and BL2, the second interlayer insulating layer IL2, and the first via insulating layer 11 may have at least one single-layer or multi-layer structure of silicon oxide, silicon nitride, silicon oxynitride, SiCN, and porous insulating material.

A back surface SB2_B of the second substrate SB2 may be covered with the first and second lower insulating layers BL1 and BL2. The second bonding pad CP2 may be disposed in the second lower insulating layer BL2. A lower surface of the second bonding pad CP2 is in contact with an upper surface of the first bonding pad CP1. A lower surface of the second lower insulating layer BL2 is in contact with an upper surface of the first interlayer insulating layer IL1.

Second device isolation portions ST2 may be disposed on a front surface SB2_F of the second substrate SB2 to define active regions for the source follower transistors DX, selection transistors SX, and second peripheral transistors PTR2. A source follower transistors DX, selection transistors SX, second peripheral transistors PTR2, second contact plugs CT2, and second wirings IT2 may be disposed on the front surface SB2_F of the second substrate SB2, and a second interlayer insulating layer IL2 may cover the front surface SB2_F of the second substrate SB2. Third bonding pads CP3 are disposed on the uppermost end of the second interlayer insulating layer IL2.

The third semiconductor chip CH3 may include photoelectric converters PD in light-receiving regions PX to sense light. The third semiconductor chip CH3 includes a third substrate SB3 and a third interlayer insulating layer IL3. A front surface SB3_F of the third substrate SB3 faces the second semiconductor chip CH2. For example, the third substrate SB3 may be doped with impurities of the first conductivity type. For example, the first conductivity type may be P-type.

The third substrate SB3 includes a second main region MR2 and a second edge region ER2. The second main region MR2 includes a plurality of light-receiving regions PX. A deep separation portion DTI may be disposed on the third substrate SB3 to separate the light-receiving regions PX from each other. The deep separation portion DTI may have a mesh shape (or a grid pattern) when viewed in a plan view. The deep separation portion DTI may include an insulating material.

In each of the light-receiving regions PX, photoelectric converters PD may be disposed in the third substrate SB3. The photoelectric converters PD may be doped with impurities of a second conductivity type opposite to the first conductivity type. The second conductivity type may be, for example, N-type. The N-type impurity doped in the photoelectric converter PD may form a PN junction with the P-type impurity doped in the surrounding third substrate SB3 to provide a photodiode.

Third device isolation portions ST3 may be disposed on the front surface SB3_F of the third substrate SB3. The third device isolation portions ST3 may be penetrated by the deep separation portion DTI. The third device isolation portions ST3 may define active regions for the transfer transistor TX on each unit light-receiving region PX. There may be no interface between the third device isolation portions ST3 and the deep separation portion DTI.

Referring to FIG. 4, a transfer gate TG may be disposed on the front surface SB3_F of the third substrate SB3 in each unit light-receiving region PX. The transfer gate TG may be a vertical type. Alternatively, the transfer gate TG may be a planar type that remains flat and does not extend into the first substrate SB1. Adjacent to the transfer gate TG on each unit light-receiving region PX, a floating diffusion region FD may be disposed in the third substrate SB3. For example, the floating diffusion region FD may be doped with impurities of the second conductivity type.

Third contact plugs CT3 and third wirings IT3 are disposed on the front surface SB3_F of the third substrate SB3. The front surface SB3_F of the third substrate SB3 may be covered with a third interlayer insulating layer IL3. Fourth bonding pads CP4 are disposed at a lower end of the third interlayer insulating layer IL3 and are in contact with the third bonding pads CP3.

Each of the first to third contact plugs CT1 to CT3, the first to third wirings IT1 to IT3, the first landing wiring LT1, and the first to fourth bonding pads CP1 to CP4 may include a metal such as aluminum, copper, tungsten, titanium, and tantalum. The third interlayer insulating layer IL3 may have a single-layer or multi-layer structure of at least one of silicon oxide, silicon nitride, silicon oxynitride, SiCN, and porous insulator.

The back surface SB3_B of the third substrate SB3 may be covered with a fixed charge layer FL. The fixed charge layer FL may have a negative fixed charge. The fixed charge layer FL may be formed of metal oxide or metal fluoride including at least one metal selected from the group including hafnium (Hf), zirconium (Zr), aluminum (Al), tantalum (Ta), titanium (Ti), yttrium, and lanthanoid. For example, the fixed charge layer FL may be a hafnium oxide layer or an aluminum oxide layer. In this case, hole accumulation may occur around the fixed charge layer FL. As a result, occurrence of dark current and white spots may be effectively reduced.

A light blocking grid pattern WG and a first optical black pattern BT are disposed on the fixed charge layer FL. The light blocking grid pattern WG may be disposed in the second main region MR2 and may overlap the deep separation portion DTI. The first optical black pattern BT is disposed in the second edge region ER2. The light blocking grid pattern WG and the first optical black pattern BT may be formed of the same material and have the same thickness. The light blocking grid pattern WG and the first optical black pattern BT may include, for example, at least one of titanium, titanium nitride, and tungsten.

A color filter array including color filters CF1 and CF2 may be disposed between the light blocking grid patterns WG. Each of the color filters CF1 and CF2 may allow one specific color of light to pass through, either blue, green, or red, so that CF1 and CF2 may each be a blue filter, a green filter, or a red filter, depending on a specific configuration. As another example, the color filters CF1 and CF2 may include other colors such as cyan, magenta, or yellow. The color filters CF1 and CF2 may be arranged in various patterns, including a Bayer pattern, a 2×2 Tetra pattern, a 3×3 Nona pattern, or a 4×4 Hexadeca pattern. A second optical black pattern CFB may be disposed on the first optical black pattern BT. The second optical black pattern CFB may be formed of the same material as the blue color filter.

Microlenses ML may be disposed on the color filters CF1 and CF2. A lens residual layer MLR may be disposed on the second optical black pattern CFB. The lens residual layer MLR may include the same transparent material as the microlenses ML.

The image sensor 1000 may be a back light-receiving image sensor. Light may be incident into the third substrate SB3 through the back surface SB3_B of the third substrate SB3. Electron-hole pairs may be created at the PN junction by incident light. Electrons generated in this way may be moved to the photoelectric converter PD. When a voltage is applied to the transfer gate TG, the electrons may move to the floating diffusion region FD. The floating diffusion regions FD may be connected to the source follower gates SF, respectively, through the third contact plugs CT3, the third wirings IT3, the fourth bonding pads CP4, the third bonding pads CP3, the second wirings IT2, and the second contact plugs CT2.

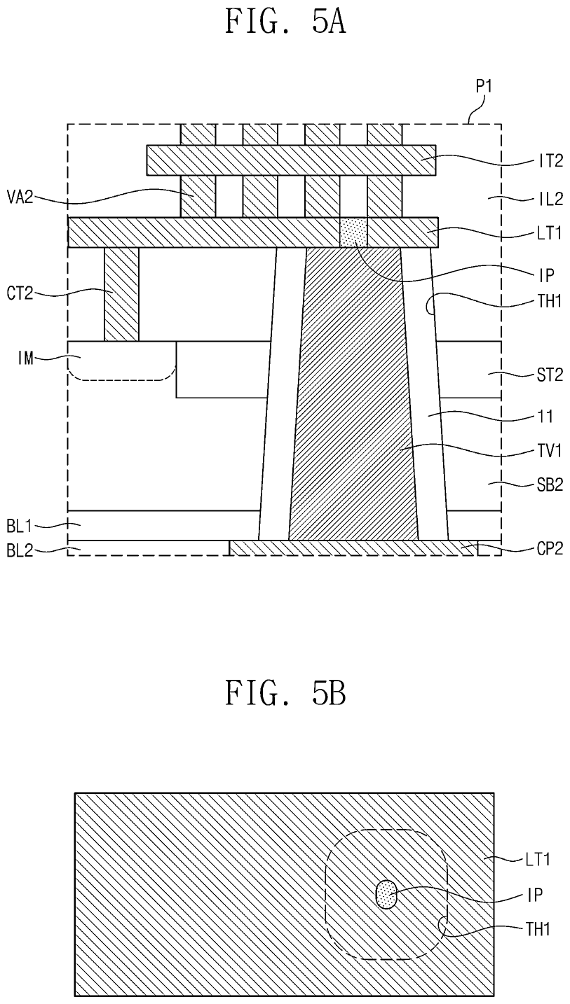

FIG. 5A is an enlarged view of portion ‘P’ of FIG. 4 according to embodiments of the present disclosure. FIG. 5B is a plan view showing a portion of FIG. 5A.

Referring to FIGS. 4, 5A, and 5B, source/drain regions IM of the second peripheral transistor PTR2 may be formed on the second substrate SB2. The source/drain regions IM may refer to either one or both of a source region and a drain region. Some of the second contact plugs CT2 may be in contact with the source/drain regions IM. The first through via TV1 may penetrate a portion of the first lower insulating layer BL1, the second substrate SB2, the second device isolation portion ST2, and a portion of the second interlayer insulating layer IL2 to connect the second boding pad CP2 to the first landing wiring LT1. A first via insulating layer 11 may be interposed between the first through via TV1 and the second substrate SB2. The first through via TV1 may include metal such as copper or tungsten. The first through via TV1 may have a width that narrows as it extends upward. In other words, the first through via TV1 may taper with its width decreasing as it extends upward. The first through via TV1 and the first via insulating layer 11 may be disposed in the through via hole TH1.

A plurality of via plugs VA2 may be disposed between the first landing wiring LT1 and the second wiring IT2 disposed thereon. The first landing wiring LT1 may be in contact with the first through via TV1. A mark pattern IP may be a distinct feature integrated into the first landing wiring LT1 to confirm the openness of the through via hole TH1 during its formation, thereby reducing defects related to incomplete openings. The mark pattern IP may penetrate the first landing wiring LT1. The mark pattern IP may have the same thickness as the first landing wiring LT1 and may be made from a material different from the first landing writing LT1.

The mark pattern IP may be formed of a material different from that of the first landing wiring LT1. For example, the mark pattern IP may include at least one of silicon oxide, silicon nitride, silicon oxynitride, polysilicon, and silicon germanium. Alternatively, the mark pattern IP may include a different metal from the first landing wiring LT1. When viewed above in a plan view, the mark pattern IP may be disposed within the through via hole TH1. The mark pattern IP may vertically overlap and contact the first through via TV1. A planar shape of the mark pattern IP may be variously changed, such as circular, oval, square, polygon, cross, or closed curve.

When forming the through via hole TH1, openness of the through via hole TH1 may be confirmed by the mark pattern IP. Accordingly, defects related to incomplete openings in the through via hole TH1 may be reduced. As a result, an image sensor with improved reliability may be provided.

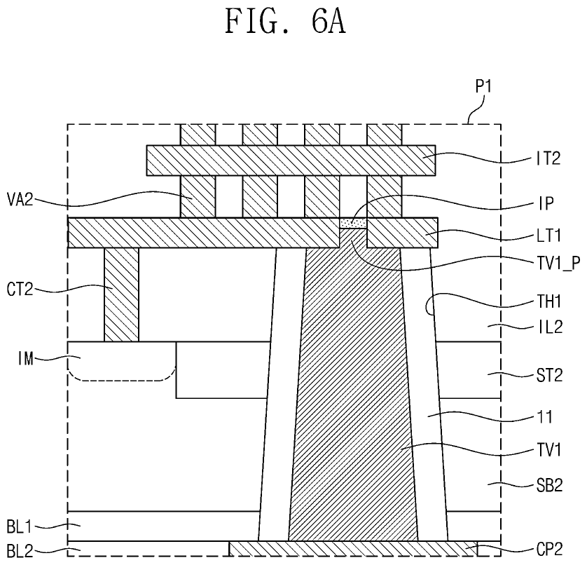

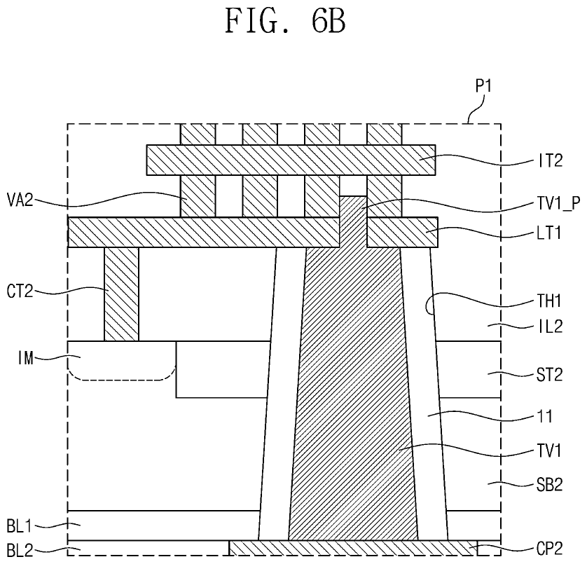

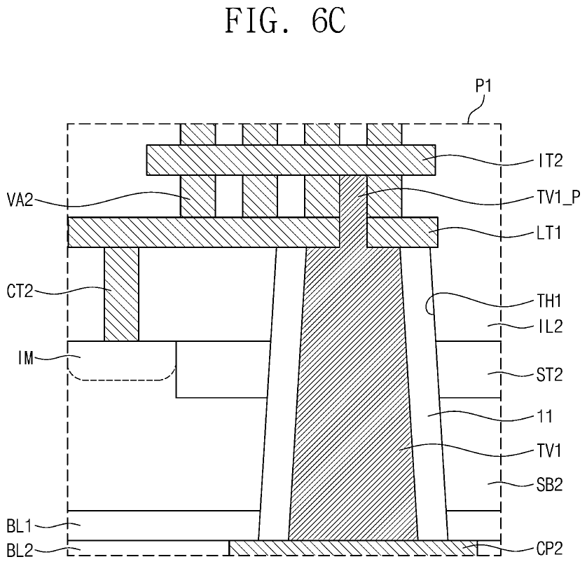

FIGS. 6A to 6C are enlarged views of portion ‘P1’ of FIG. 4 according to embodiments of the present disclosure.

Referring to FIG. 6A, a portion TV1_P of the first through via TV1 may be inserted into the first landing wiring LT1 and cover an inner wall of the first landing wiring LT1. A thickness of the mark pattern IP may be thinner than the first landing wiring LT1. As the first through via TV1 extend to cover the inner wall of the first landing wiring LT1, the junction area between the first through via TV1 and the first landing wiring LT1 expands, thereby increasing an electric current flow therebetween. Resistance may be reduced and mechanical (physical) bonding therebetween may be improved. Accordingly, an image sensor with improved reliability may be provided.

Alternatively, referring to FIG. 6B, a portion TV1_P of the first through via TV1 may be inserted into the first landing wiring LT1 to cover not only the inner wall of the first landing wiring LT1 but also the sidewall of at least one of the via plugs VA2. In the structure of the image sensor shown in FIG. 6B, the mark pattern IP of FIGS. 5A and 6A may be omitted, because the first through via TV1 extends upward to fill the entire disconnected area (i.e., the through via hole TH1) of the first landing wiring LT1, leaving no remaining space for the mark pattern IP to be inserted.

Alternatively, referring to FIG. 6C, a portion TV1_P of the first through via TV1 may extend further from the state of FIG. 6B and may be in contact with a lower surface of the second wiring IT2.

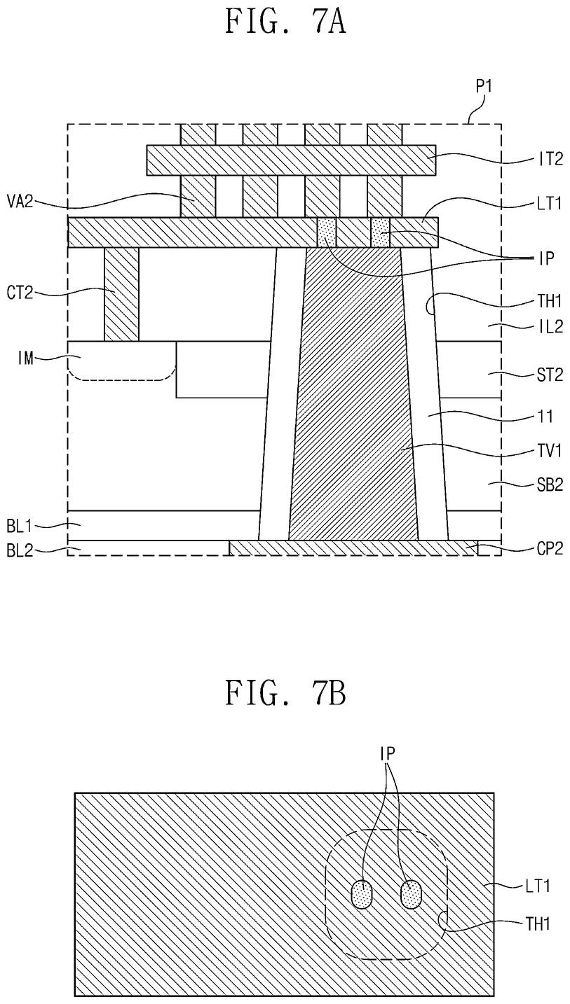

FIG. 7A is an enlarged view of portion ‘P1’ of FIG. 4 according to embodiments of the present disclosure. FIG. 7B is a plan view showing a portion of FIG. 7A.

Referring to FIGS. 7A and 7B, two mark patterns IP may be disposed in the first landing wiring LT1. The two mark patterns IP may be in contact with the first through via TV1. The two mark patterns IP may be disposed in the through via hole TH1 when viewed above. In this example, the number of mark patterns IP is two, but the present disclosure is not limited thereto and three or more mark patterns IP may be provided. Additionally, arrangement or spacing of the mark patterns IP may be variously changed.

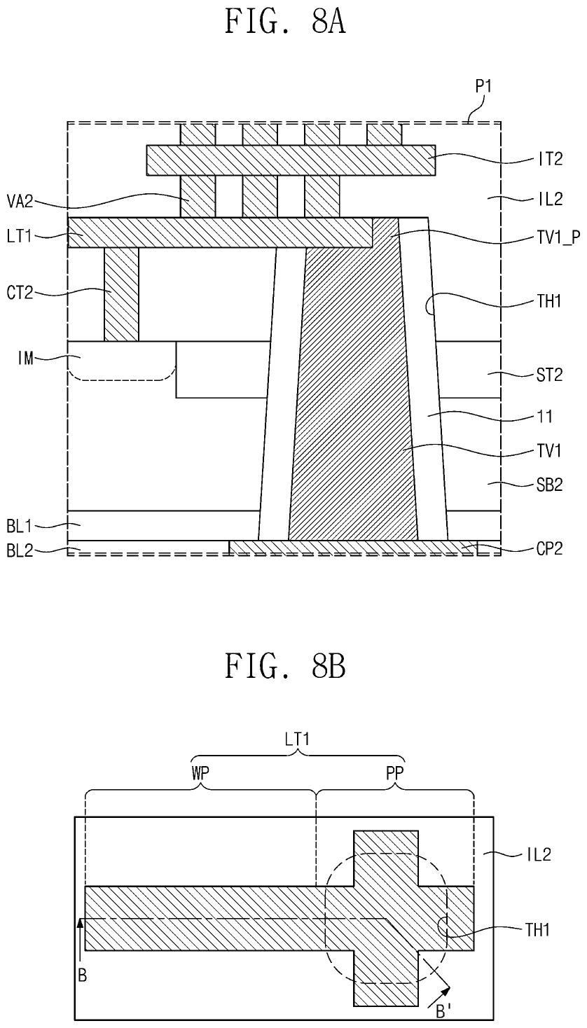

FIG. 8A is an enlarged view of portion ‘P1’ of FIG. 4 according to embodiments of the present disclosure. FIG. 8B is a plan view showing a portion of FIG. 8A. FIG. 8A may correspond to a cross section of FIG. 8B taken along line B-B′.

Referring to FIGS. 8A and 8B, the first landing wiring LT1 may include a wiring portion WP and a pad portion PP. The pad portion PP is in contact with the first through via TV1. The pad portion PP may have a cross shape when viewed in a plan view. In another example, the pad portion PP may have a line shape or a polygonal shape when viewed in a plan view. One edge of the pad portion PP may be exposed by the through via hole TH1. A portion TV1_P of the first through via TV1 may cover a side surface of the pad portion PP. The first through via TV1 may cover all side surfaces of the corners of the pad portion PP. As the first through via TV1 covers the inner wall of the first landing wiring LT1, the junction area between the first through via TV1 and the first landing wiring LT1 may expand, thereby reducing electrical resistance therebetween and improving mechanical (physical) bonding strength therebetween. Accordingly, an image sensor with improved reliability may be provided. Other structures may be the same as or similar to those described above.

When forming the through via hole TH1 as shown in FIGS. 8A and 8B, the openness of the through via hole TH1 can be verified by ensuring that one edge of the pad portion PP is exposed. Accordingly, the occurrence of incomplete openings in the through via hole TH1 may be reduced. In addition, a portion TV1_P of the first through via TV1 may cover the side surface of the pad portion PP, thereby increasing the bonding area between the first through via TV1 and the first landing wiring LT1 and reducing electrical resistance therebetween. Accordingly, an image sensor with improved reliability may be provided.

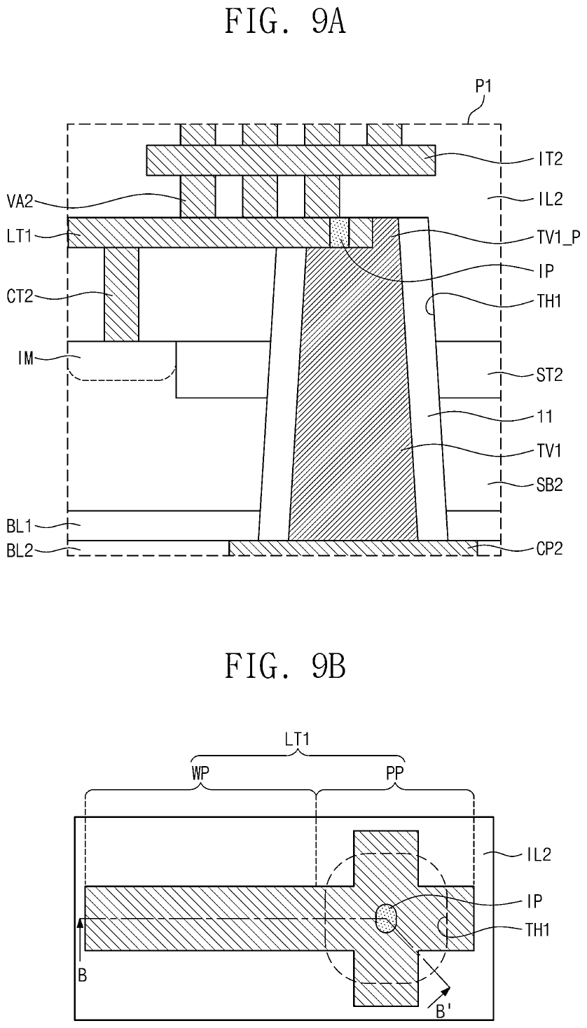

FIG. 9A is an enlarged view of portion ‘P1’ of FIG. 4 according to embodiments of the present disclosure. FIG. 9B is a plan view showing a portion of FIG. 9A.

Referring to FIGS. 9A and 9B, the first landing wiring LT1 may include a wiring portion WP and a pad portion PP. The pad portion PP may have a cross shape when viewed in a plan view. A mark pattern IP may be disposed at a center of the pad portion PP. Other structures may be the same as or similar to those described above.

Although FIG. 4 shows that one first through via TV penetrates the second substrate SB2 of the second semiconductor chip CH2, the number of first through vias TV is not limited thereto and may be provided in the plural. Additionally, additional through vias may be provided to penetrate at least one of the first substrate SB1 of the first semiconductor chip CH1 and the third substrate SB3 of the third semiconductor chip CH3.

In the specification, a concept of individual semiconductor chips may be defined by a stacked structure formed by several semiconductor wafers which are different from each other. An interface between the semiconductor chips may not be definitely observed because of bonding shape, bonding method, or bonding material between the semiconductor chips, and the stacked structure having an ambiguous interface is not excluded from the concept of the individual semiconductor chips.

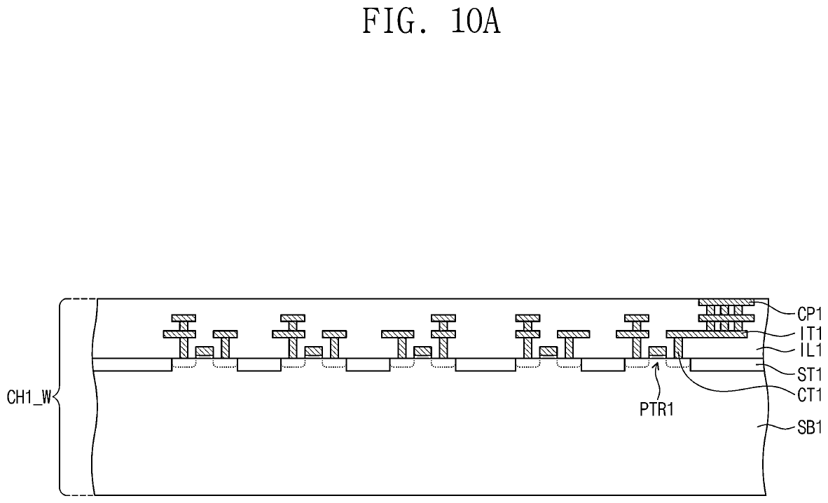

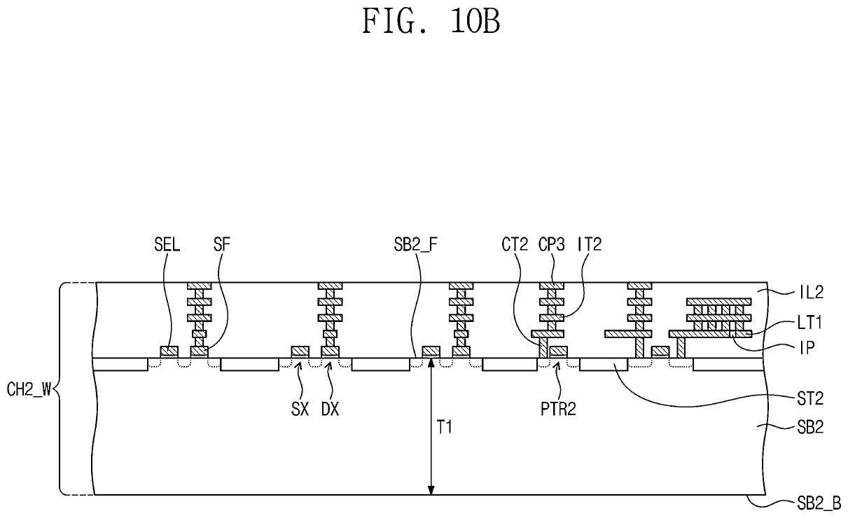

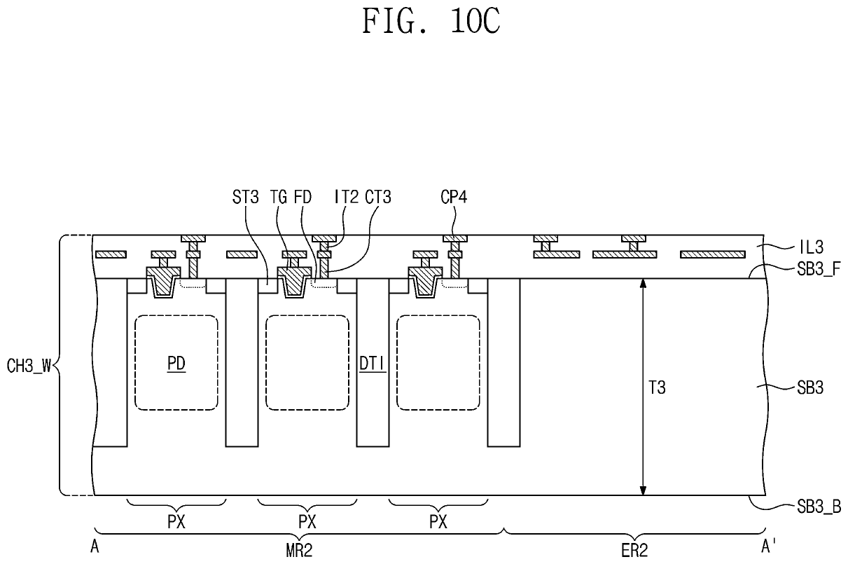

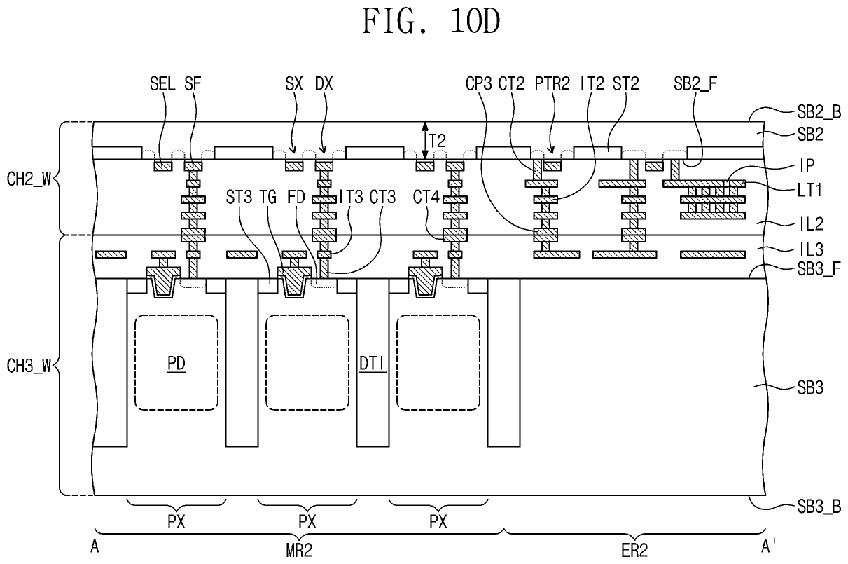

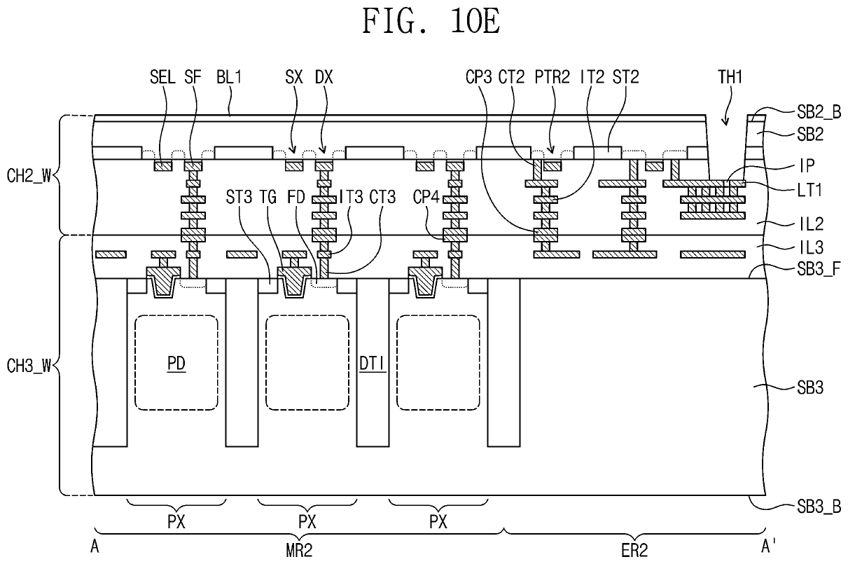

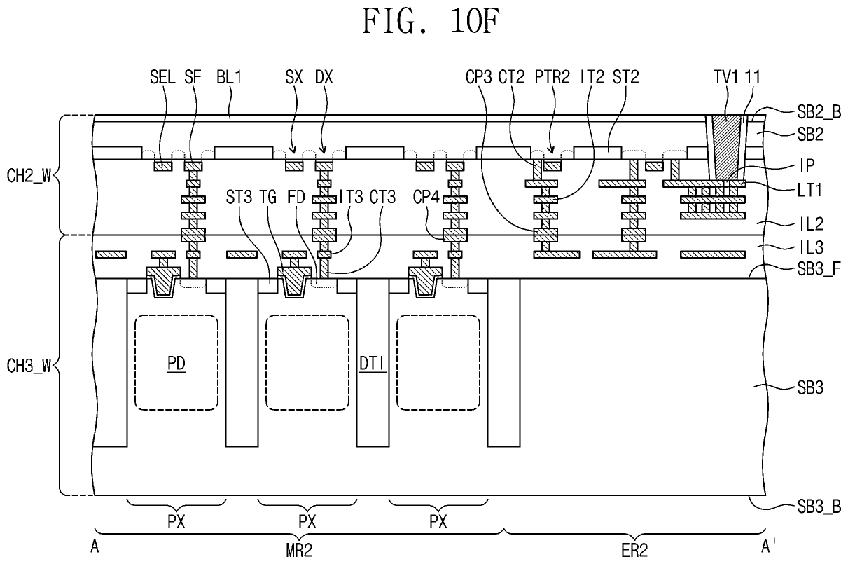

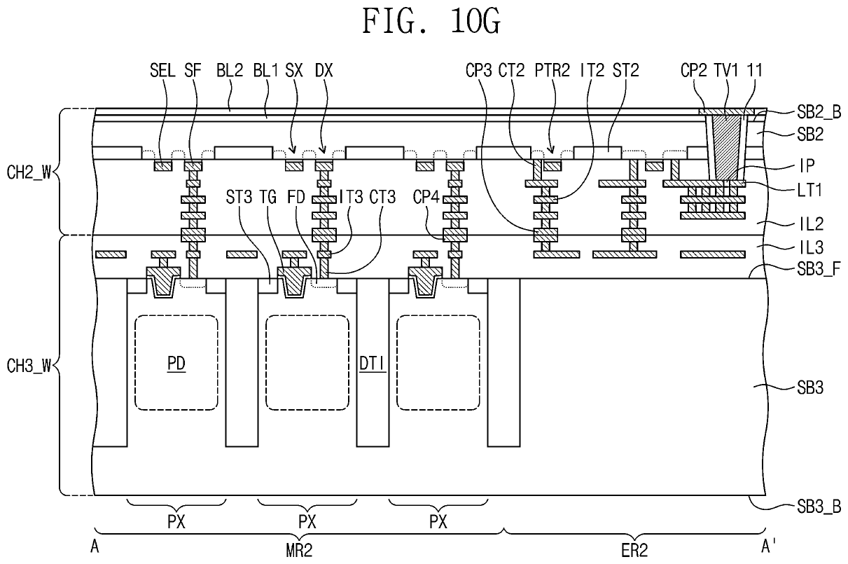

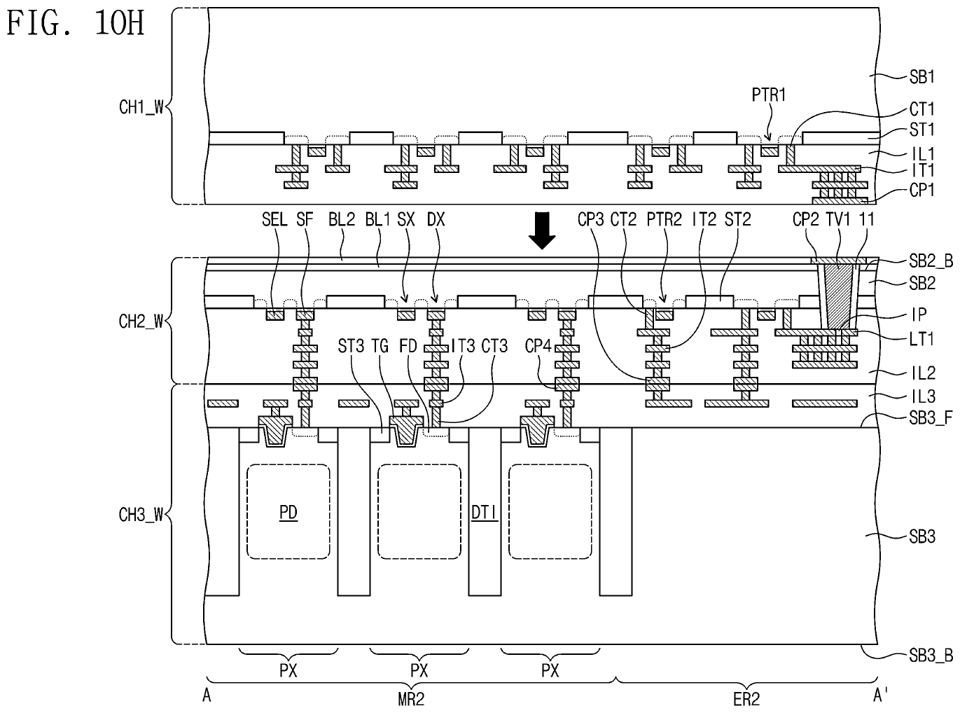

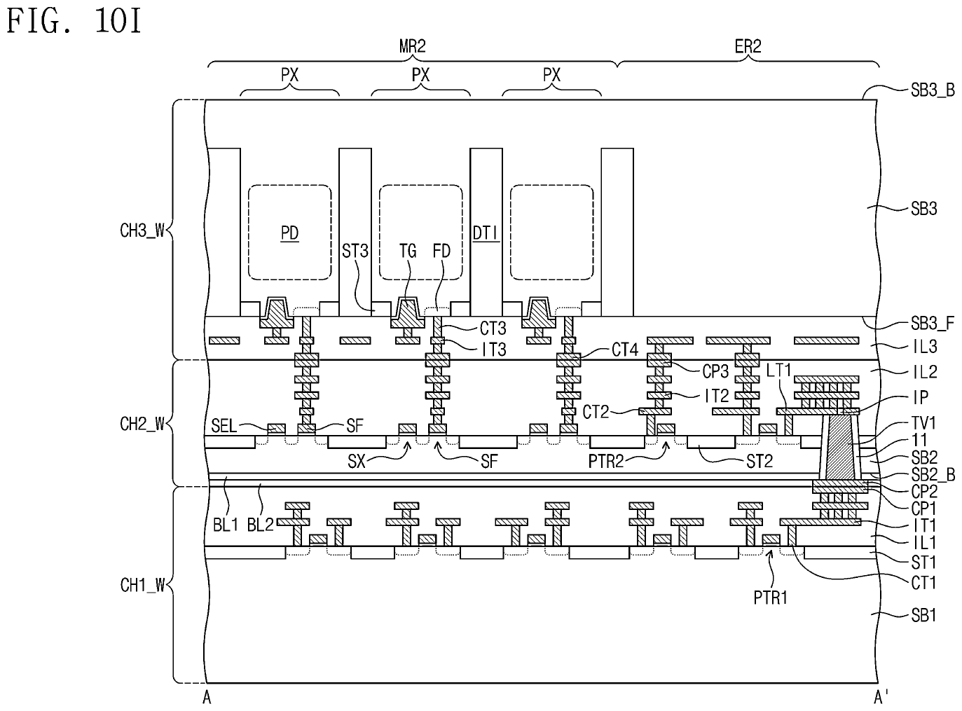

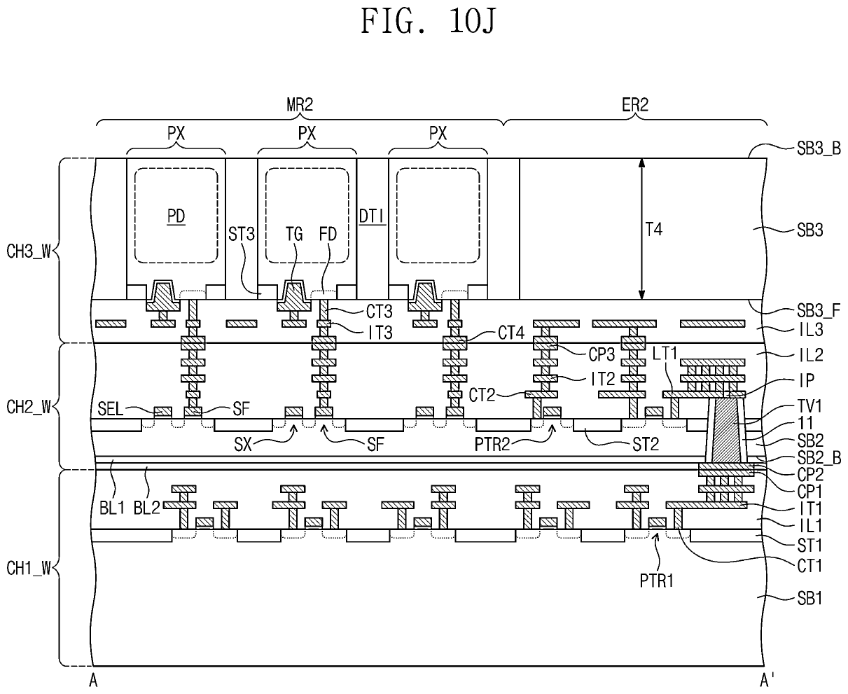

FIGS. 10A to 10J are cross-sectional views showing a manufacturing process of the image sensor having the cross-section of FIG. 4.

Referring to FIG. 10A, a first semiconductor chip wafer CH1_W is manufactured through a regular or standard manufacturing process. The first semiconductor chip wafer CH1_W may include device regions and a scribe lane region therebetween. In the first semiconductor chip wafer CH1_W, each device region may include a first substrate SB1, first device isolation portions ST1, first peripheral transistors PTR1, first contact plugs CT1, first wirings IT1, first interlayer insulating layer IL1, and first bonding pad CP1 as shown in FIG. 10A.

Referring to FIG. 10B, a second semiconductor chip wafer CH2_W is manufactured through a regular or standard manufacturing process. The second semiconductor chip wafer CH2_W may include device regions and a scribe lane region therebetween. In the second semiconductor chip wafer CH2_W, each device region may include a second substrate SB2, a second device isolation portion ST2, a source follower transistor DX, a selection transistor SX, second peripheral transistors PTR2, second contact plugs CT2, second wirings IT2, a first landing wiring LT1, a second interlayer insulating layer IL2, and a third bonding pad CP3 as shown in FIG. 10B. The second substrate SB2 may have a first thickness T1. As shown in FIG. 5A, the mark pattern IP may exist in the first landing wiring LT1.

Referring to FIG. 10C, a third semiconductor chip wafer CH3_W is manufactured through a regular or standard manufacturing process. The third semiconductor chip wafer CH3_W may include device regions and a scribe lane region therebetween. In the third semiconductor chip wafer CH3_W, each device region may include a third substrate SB3, a third device isolation portion ST3, a deep separation portion DTI, a transfer gate TG, a floating diffusion region FD, third contact plugs CT3, third wirings IT3, and a fourth bonding pad CP4 as shown in FIG. 10C. The third substrate SB3 may have a third thickness T3. The deep separation portion DTI may have a lower depth than a back surface SB3_B of the third substrate SB3.

Referring to FIG. 10D, a thermocompression process is performed to turn the second semiconductor chip wafer CH2_W of FIG. 10B over and bonded to the third semiconductor chip wafer CH3_W of FIG. 10C. Accordingly, the third interlayer insulating layer IL3 may be in contact with the second interlayer insulating layer IL2 and the fourth bonding pads CP4 may be in contact with the third bonding pads CP3. A back grinding process is performed on the back surface SB2_B of the second substrate SB2 of the second semiconductor chip wafer CH2_W to thin the second substrate SB2 to a second thickness T2.

Referring to FIGS. 5A, 5B, and 10E, a first lower insulating layer BL1 is formed on the back surface SB2_B of the second substrate SB2. The first lower insulating layer BL1, the second substrate SB2, the second device isolation portion ST2, and the second interlayer insulating layer IL2 are etched to form a through via hole TH1 exposing the first landing wiring LT1. In this case, the mark pattern IP of the first landing wiring LT1 may be exposed. After forming the through via hole TH1, whether the mark pattern IP is exposed may be checked using a scanning electron microscope. Accordingly, when forming the through via hole TH1, openness of the through via hole TH1 may be confirmed by the mark pattern IP. Accordingly, the occurrence of incomplete openings in the through via hole TH1 may be reduced. As a result, an image sensor with improved reliability may be provided.

Referring to FIGS. 5A, 5B, and 10F, in the state of FIG. 10E, an insulating layer is conformally formed on the first lower insulating layer BL1 to cover an inner wall of the through via hole TH1, and then an anisotropic etching process is performed on the insulating layer to open a bottom surface of the through via hole TH1 and form a first via insulating layer 11 simultaneously. Even when forming the first via insulating layer 11, openness of the through via hole TH1 may be confirmed by the mark pattern IP. A conductive layer is deposited to fill the through via hole TH1, and a planarization process is performed to form a first through via TV1.

Referring to FIG. 10G, a second lower insulating layer BL2 is formed on the first lower insulating layer BL1. A second bonding pad CP2 is formed in the second lower insulating layer BL2 in contact with the first through via TV1.

Referring to FIGS. 10H and 10I, a thermocompression process is performed to flip the first semiconductor chip wafer CH1_W of FIG. 10A over and bond the first semiconductor chip wafer CH1_W to the second semiconductor chip wafer CH2_W. Accordingly, the second lower insulating layer BL2 may be in contact with the first interlayer insulating layer IL1 and the second bonding pad CP2 may be in contact with the first bonding pad CP1. Accordingly, the bonded structure is turned over. Therefore, the back surface SB3_B of the third substrate SB3 of the third semiconductor chip wafer CH3_W may face upward.

Referring to FIG. 10J, a back grinding process is performed on the back surface SB3_B of the third substrate SB3. This process may reduce the thickness of the third substrate SB3 from an initial thickness (i.e., a third thickness T3) to a thinner thickness (i.e., a fourth thickness T4), as shown in FIG. 10C. Through the back grinding process, a portion of the deep separation portion DTI may be removed and exposed.

Subsequently, referring to FIG. 4, a regular or standard manufacturing process may be performed to form a fixed charge layer FL, a light blocking grid pattern WG, and color filters CF1 and CF2, a first optical black pattern BT, a second optical black pattern CFB, microlenses ML, and a lens residual layer MLR on the back surface SB3_B of the third substrate SB3. Then, a sawing process of cutting the scribe lane region may be performed to manufacture the image sensor 1000 of FIG. 4.

Accordingly, in the method of manufacturing the image sensor according to the present disclosure, the occurrence of incomplete openings in the through via hole TH1 may be reduced, thereby reducing process defects and improving yield.

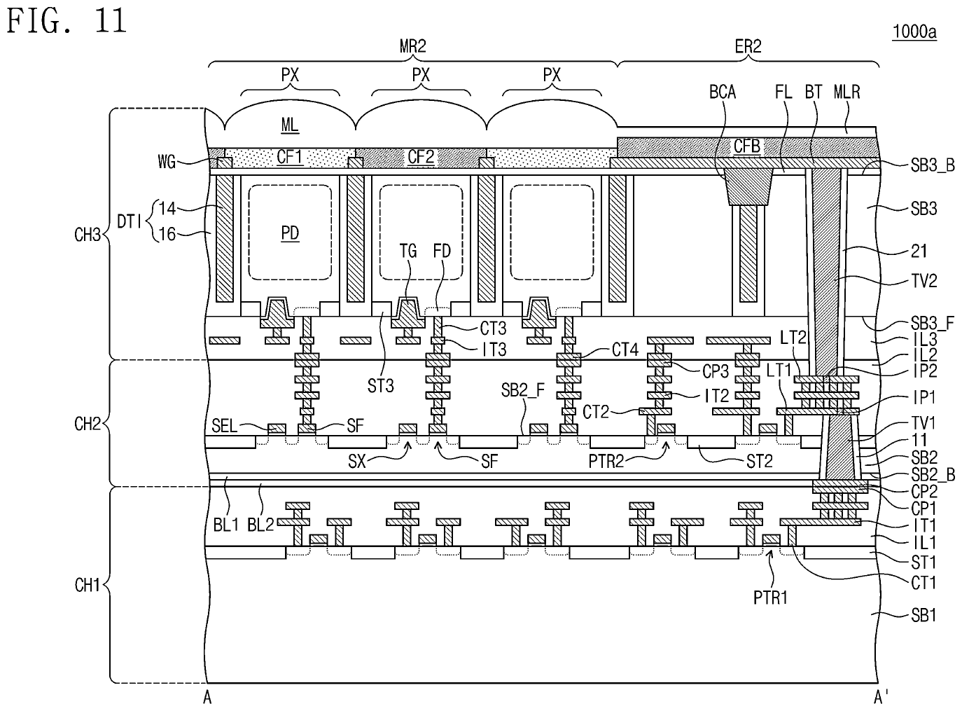

FIG. 11 is a cross-sectional view of the image sensor of FIG. 3 taken along line A-A′ according to embodiments of the present disclosure.

Referring to FIG. 11, in an image sensor 1000a according to the present example, the second semiconductor chip CH2 may include a first landing wiring LT1 and a second landing wiring LT2 that are spaced apart from each other. A first mark pattern IP1 is disposed in the first landing wiring LT1, and a second mark pattern IP2 is disposed in the second landing wiring LT2. The first through via TV1 may penetrate the second substrate SB2 and may be in contact with the first landing wiring LT1 and the first mark pattern IP1.

The deep separation portion DTI included in the third semiconductor chip CH3 may include a separation conductive pattern 14 and a separation insulating pattern 16. The separation insulating pattern 16 may be interposed between the separation conductive pattern 14 and the third substrate SB3. In the second edge region ER2, a back contact pattern BCA may penetrate the fixed charge layer FL, a portion of the third substrate SB3, and a portion of the deep separation portion DTI to connect the separation conductive pattern 14 to the first optical black pattern BT. In this case, the first optical black pattern BT may also be called a ‘back wiring’.

In the second edge region ER2, the second through via TV2 connects the fixed charge layer FL, the third substrate SB3, the third interlayer insulating layer IL3, and a portion of the second interlayer insulating layer IL2. The first optical black pattern BT may be connected to the second landing wiring LT2. The second through via TV2 may include metal such as copper or tungsten. The second through via TV2 may be in contact with the second mark pattern IP2. The second through via TV2 and the second mark pattern IP2 may have the same/similar structure as the first through via TV1 and the first mark pattern IP1 described with reference to FIGS. 5A to 9B. A second via insulating layer 21 may be interposed between the second through via TV2 and the third substrate SB3. The second via insulating layer 21 may be formed of silicon oxide. Other structures may be the same/similar to those described with reference to FIG. 4.

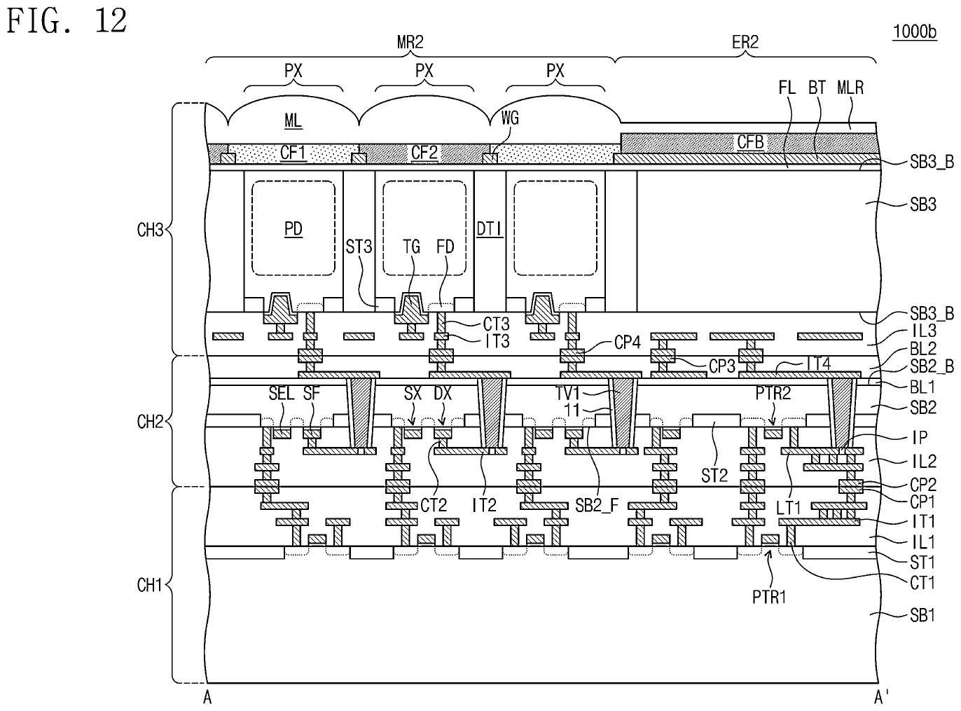

FIG. 12 is a cross-sectional view of the image sensor of FIG. 3 taken along line A-A′ according to embodiments of the present disclosure.

Referring to FIG. 12, in an image sensor 1000b according to the present example, the second semiconductor chip CH2 may have a structure similar to the structure of the second semiconductor chip CH2 of FIG. 4 turned over. Specifically, in the second semiconductor chip CH2 according to the present example, a front surface SB2_F of the second substrate SB faces the first semiconductor chip CH1, and a back surface SB2_B of the second substrate SB faces the third semiconductor chip CH3. First and second lower insulating layers BL1 and BL2 are sequentially stacked on the back surface SB2_B of the second substrate SB. The first landing wiring LT1 may be provided in the plural, and some of the first landing wirings LT1 may overlap the second main region MR2. Some of the first landing wirings LT1 may extend to vertically overlap the source follower gates SF.

The first through vias TV1 penetrate through the first lower insulating layer BL1, the second substrate SB2, the second device isolation portion ST2, and a portion of the second interlayer insulating layer IL2 to be connected to the first landing wirings LT1, respectively. The first through vias TV1 may taper downward so that the width of the first through vias TV1 narrows downward. Mark patterns IP may be disposed in the first landing wirings LT1, respectively. Fourth wirings IT4 and third bonding pads CP3 may be disposed in the second lower insulating layer BL2. The fourth wirings IT4 may connect the first through vias TV1 to the third bonding pads CP3. The first landing wirings LT1 and the mark patterns IP may have the same/similar structure to the structure described with reference to FIGS. 5A to 9B. Other structures may be the same/similar to FIG. 4.

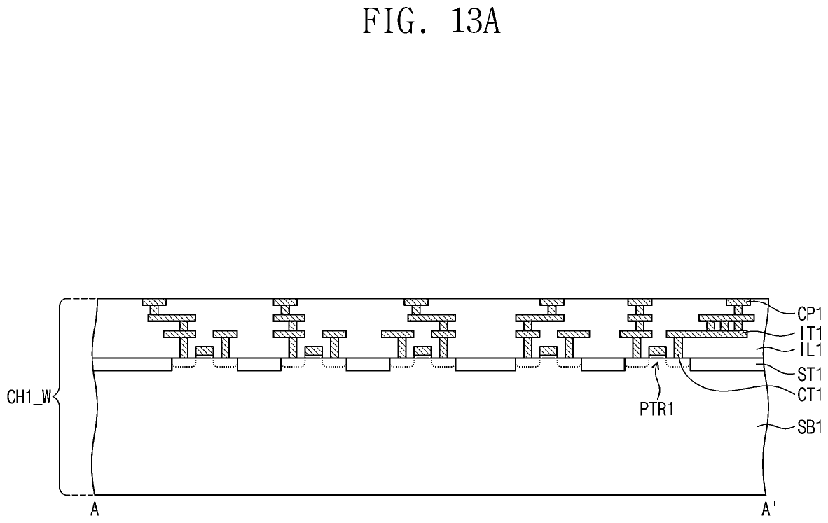

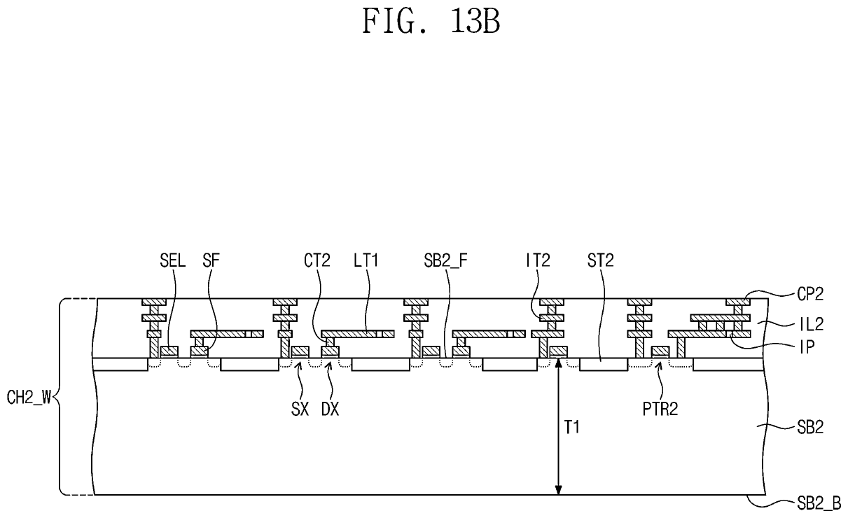

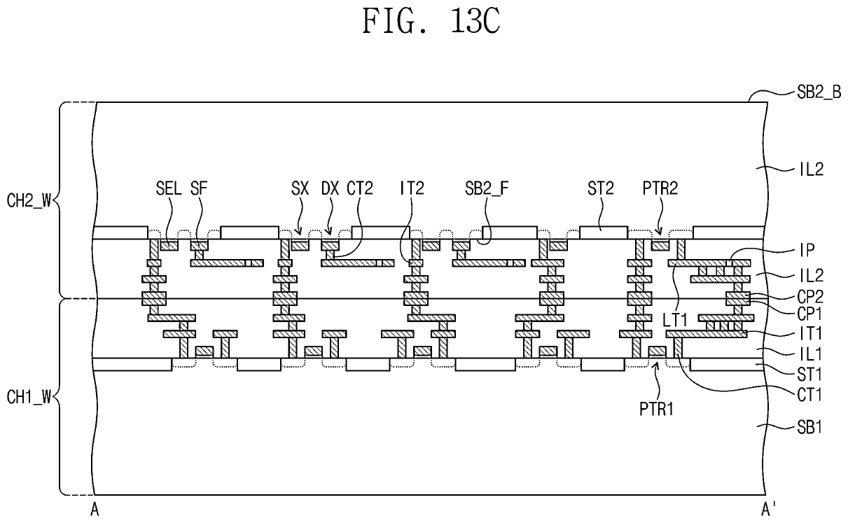

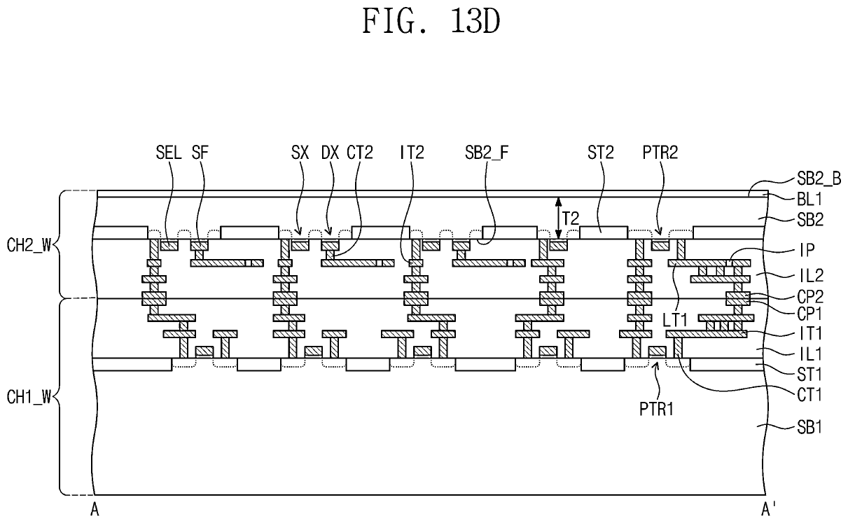

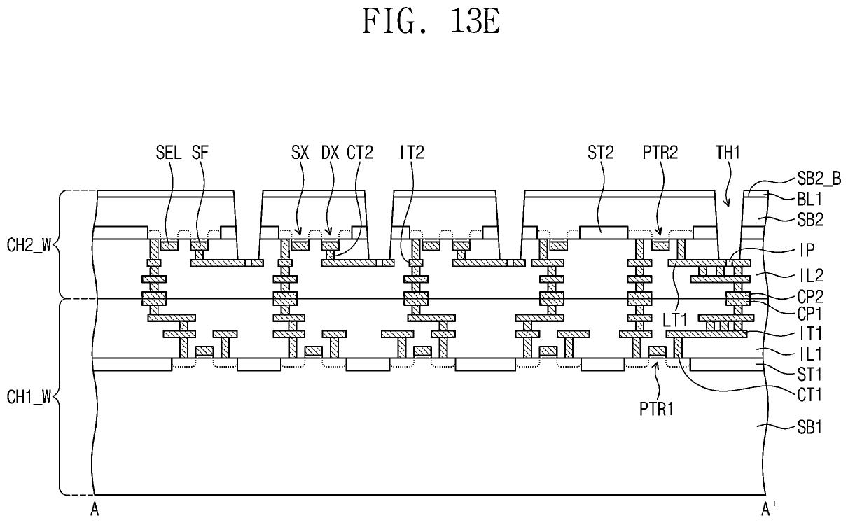

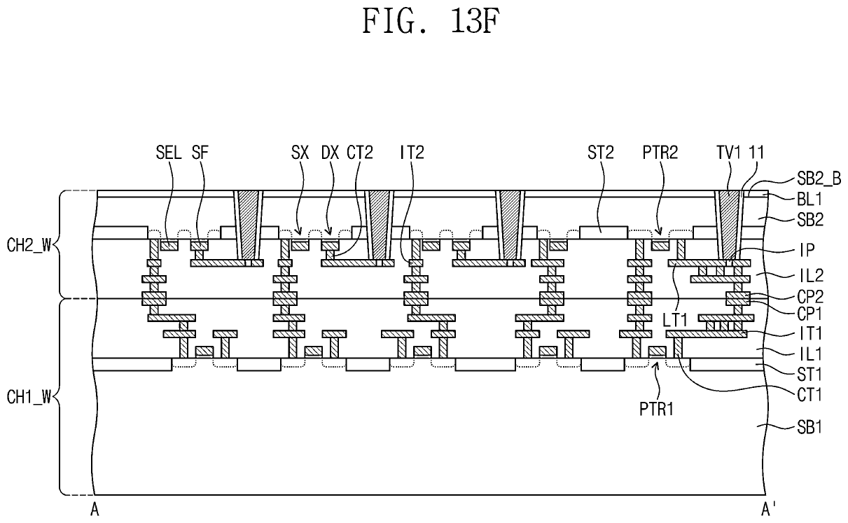

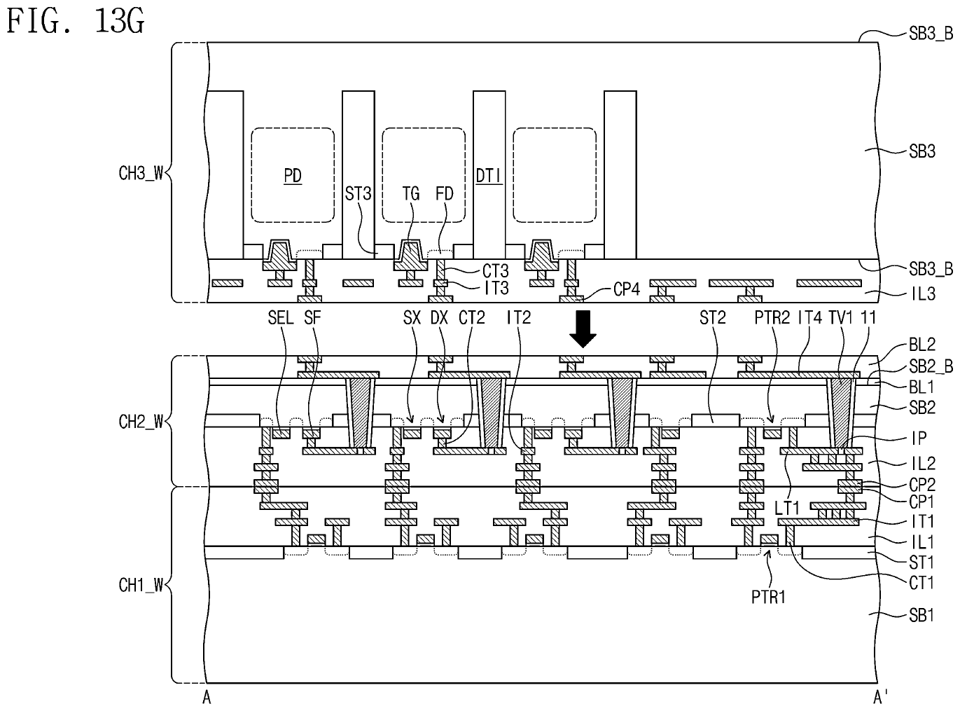

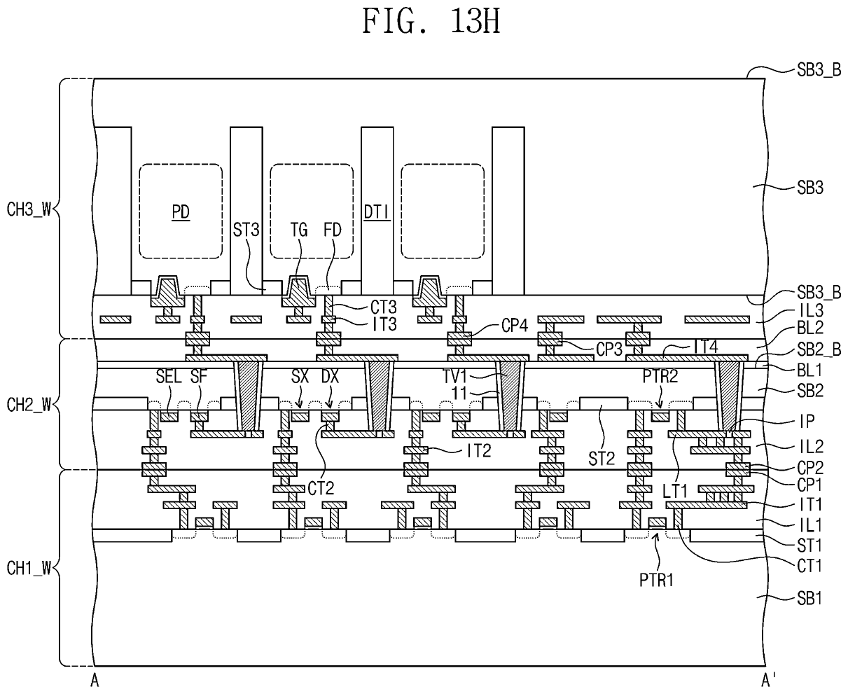

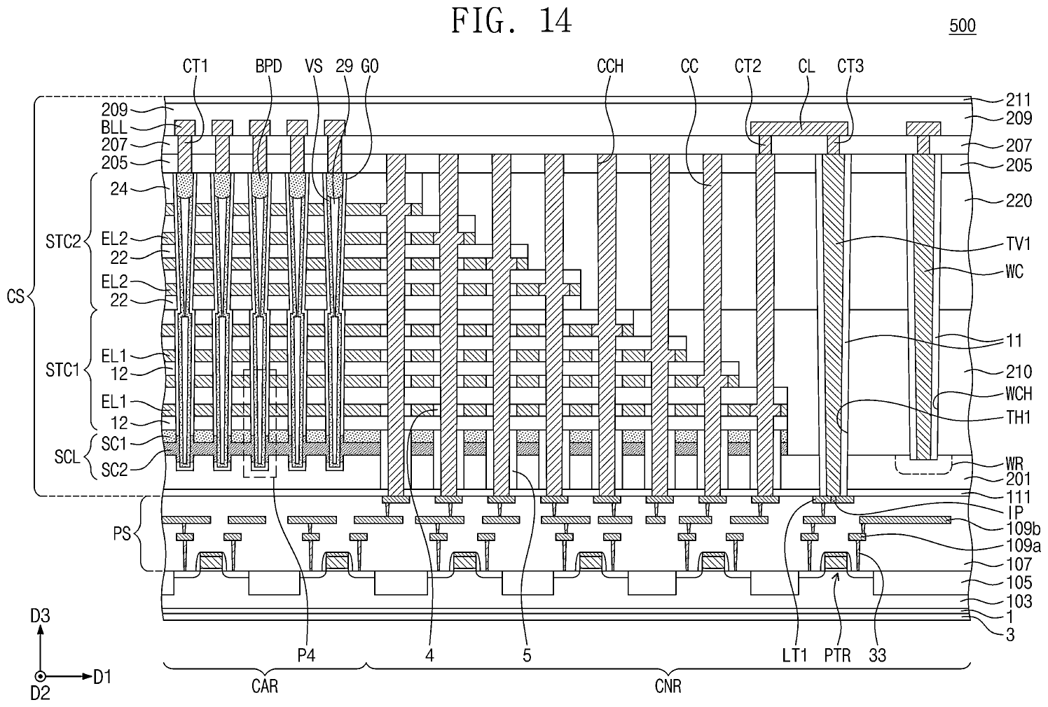

FIGS. 13A to 13H are cross-sectional views sequentially showing a process of manufacturing the image sensor of FIG. 12.

Referring to FIG. 13A, a first semiconductor chip wafer CH1_W is manufactured through a regular or standard manufacturing process. The first semiconductor chip wafer CH1_W may include device regions and a scribe lane region therebetween. In the first semiconductor chip wafer CH1_W, each of the device regions includes the first substrate SB1, the first device isolation portions ST1, the first peripheral transistors PTR1, the first contact plugs CT1, the first wirings IT1, the interlayer insulating layer IL1, and first bonding pads CP1 as shown in FIG. 13A. The first bonding pads CP1 may be disposed not only at an edge of the first substrate SB1 but also at a center thereof.

Referring to FIG. 13B, a second semiconductor chip wafer CH2_W is manufactured through a regular or standard manufacturing process. The second semiconductor chip wafer CH2_W may include device regions and a scribe lane region therebetween. In the second semiconductor chip wafer CH2_W, each of the device regions includes the second substrate SB2, the second device isolation portion ST2, the source follower transistor DX, the selection transistor SX, the second peripheral transistors PTR2, the second contact plugs CT2, the second wirings IT2, the first landing wirings LT1, the second interlayer insulating layer IL2, and second bonding pads CP2 as shown in FIG. 13B.

Referring to FIG. 13C, a thermocompression process is performed to turn the second semiconductor chip wafer CH2_W of FIG. 13B over and bonded to the first semiconductor chip wafer CH1_W of FIG. 13A. Accordingly, the first interlayer insulating layer IL1 may be in contact with the second interlayer insulating layer IL2 and the first bonding pads CP1 may be in contact with the second bonding pads CP2.

Referring to FIG. 13D, a back grinding process is performed on the back surface SB2_B of the second substrate SB2 of the second semiconductor chip wafer CH2_W to thin the second substrate SB2 to a second thickness T2. A first lower insulating layer BL1 is formed on the back surface SB2_B of the second substrate SB2.

Referring to FIGS. 5A, 5B, and 13E, the first lower insulating layer BL1, the second substrate SB2, the second device isolation portion ST2, and the second interlayer insulating layer IL2 are etched to form through via holes TH1 that are expose the first landing wirings LT1, respectively. In this case, the mark patterns IP of the first landing wirings LT1 may each be exposed. After forming the through via hole TH1, whether the mark pattern IP is exposed may be checked using a scanning electron microscope. Accordingly, when forming the through via hole TH1, openness of the through via hole TH1 may be confirmed by the mark pattern IP. Accordingly, the occurrence of incomplete openings in the through via hole TH1 may be reduced. As a result, an image sensor with improved reliability may be provided.

Referring to FIG. 13F, an insulating layer is conformally formed on the first lower insulating layer BL1 to cover the inner wall of the through via hole TH1, and then an anisotropic etching process is performed on the insulating layer to open a bottom surface of the through via hole TH1 and form a first via insulating layer 11. Even when forming the first via insulating layer 11, the openness of the through via hole TH1 may be confirmed by the mark pattern IP. A conductive layer is deposited to fill the through via hole TH1, and a planarization process is performed to form a first through via TV1.

Referring to FIG. 13G, a second lower insulating layer BL2, fourth wirings IT4, and third bonding pads CP3 are formed on the first lower insulating layer BL1. Then, a third semiconductor chip CH3 is manufactured through a regular or standard manufacturing process as shown in FIG. 10C. The third semiconductor chip CH3 includes the third substrate SB3, the third device isolation portion ST3, the deep separation portion DTI, the transfer gate TG, the floating diffusion region FD, the third contact plug CT3, the third wirings IT3, and the fourth bonding pad CP4. The deep separation portion DTI may have a lower depth than that of the back surface SB3_B of the third substrate SB3.

Referring to FIGS. 13G and 13H, the third semiconductor chip wafer CH3_W of FIG. 10C is turned over and bonded to the second semiconductor chip wafer CH2_W. Accordingly, the second lower insulating layer BL2 may be in contact with the third interlayer insulating layer IL3 and the fourth bonding pad CP4 may be in contact with the third bonding pad CP3.

Subsequently, referring to FIG. 10J, a back grinding process is performed on the back surface SB3_B of the third substrate SB3. As a result, the third substrate SB3, which had the third thickness T3, may be thinned to a fourth thickness T4, as shown in FIG. 10C. Through the back grinding process, a portion of the deep separation portion DTI may be removed and exposed.

Subsequently, referring to FIG. 12, a regular or standard manufacturing process is performed to form a fixed charge layer FL, a light blocking grid pattern WG, and color filters CF1 and CF2, a first optical black pattern BT, a second optical black pattern CFB, microlenses ML, and a lens residual layer MLR may be formed on the back surface SB3_B of the third substrate SB3. Then, the image sensor 1000b of FIG. 12 may be manufactured by performing a sawing process of cutting the scribe lane region.

FIG. 14 is a cross-sectional view of a semiconductor memory device according to embodiments of the present disclosure.

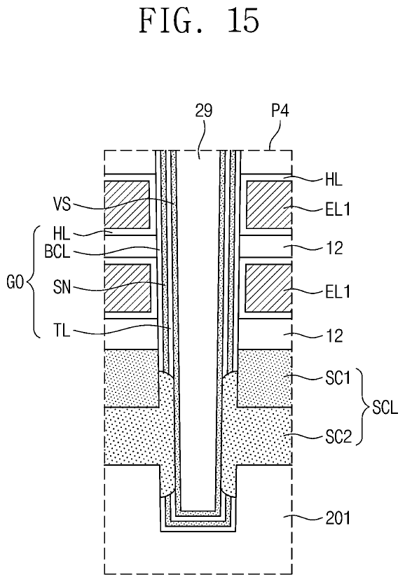

Referring to FIGS. 14 and 15, a peripheral circuit structure PS and a cell array structure CS are sequentially stacked on the substrate 103. The substrate 103 may be a silicon single crystal substrate or a silicon on insulator (SOI) substrate. A lower surface of the substrate 103 may be covered with a first lower insulating layer 1 and a second lower insulating layer 3. The first lower insulating layer 1 may have a single-layer or multi-layer structure of at least one of, for example, silicon oxide or silicon nitride. The second lower insulating layer 3 may be formed of silicon carbonitride (SiCN).

A device isolation layer 105 may be disposed on the substrate 103 to define active regions. The peripheral circuit structure PS includes peripheral circuits. Peripheral transistors PTR may be disposed on the active regions. The peripheral transistors PTR may each include a peripheral gate electrode, a peripheral gate insulating layer, and peripheral source/drain regions disposed on both sides of the substrate 103 adjacent thereto. The peripheral transistors PTR may be covered with a peripheral interlayer insulating layer 107. The peripheral interlayer insulating layer 107 may have a single-layer or multi-layer structure of at least one of a silicon oxide layer, a silicon nitride layer, a silicon oxynitride layer, and a porous insulating layer. Peripheral wirings 109a and 109b, first landing wirings LT1, and peripheral contacts 33 may be disposed in the peripheral interlayer insulating layer 107. The peripheral wirings 109a and 109b, the first landing wirings LT1 and the peripheral contacts 33 may include a conductive layer.

Some of the peripheral wirings 109a and 109b, the first landing wirings LT1 and the peripheral contacts 33 may be electrically connected to the peripheral transistors PTR. The peripheral transistors PTR, the peripheral wirings 109a and 109b, the first landing wirings LT1 and the peripheral contacts 33 may form a page buffer circuit and a decoder circuit.

An interface layer 111 is disposed on the peripheral circuit structure PS. The interface layer 111 may include a material that has etch selectivity with respect to the semiconductor layer 201 and the peripheral interlayer insulating layer 107. For example, the interface layer 111 may include silicon nitride or silicon oxide. The interface layer 111 may also be referred to as an adhesive layer.

A cell array structure CS is disposed on the interface layer 111. The cell array structure CS includes a semiconductor layer 201, a source structure SCL, a first stacked structure STC1, a second stacked structure STC2, and first to fourth upper insulating layers 205, 207, 209, and 211 which are sequentially stacked. The first stacked structure STC1 may include first electrode layers EL1 and first inter-electrode insulating layers 12 that are alternately stacked. The second stacked structure STC2 may include alternately stacked second electrode layers EL2 and second inter-electrode insulating layers 22, and a second uppermost inter-electrode insulating layer 24 disposed on the uppermost layer thereof. The semiconductor layer 201 may be, for example, a silicon single crystal layer, a silicon epitaxial layer, or an SOI substrate. For example, the semiconductor layer 201 may be doped with impurities of a first conductivity type. The impurity of the first conductivity type may be, for example, P-type boron. Alternatively, the first conductivity type impurity may be N-type such as arsenic or phosphorus.

The electrode layers ELI and EL2 may include at least one of, for example, a doped semiconductor (e.g., doped silicon, etc.), a metals (e.g., tungsten, copper, aluminum, etc.), a conductive metal nitride (e.g., titanium nitride, tantalum nitride, etc.) or a transition metal (e.g., titanium, tantalum, etc.). The inter-electrode insulating layers 12, 22, and 24 may include at least one single layer or multilayer selected from a silicon oxide layer, a silicon nitride layer, a silicon oxynitride layer, and a porous insulating layer.

The source structure SCL may include a first source pattern SC1 interposed between the inter-electrode insulating layer 12 and the semiconductor layer 201 disposed at the lowest layer thereof, and a second source pattern SC2 interposed between the first source pattern SC1 and the semiconductor layer 201. A portion of the first source pattern SCI may penetrate the second source pattern SC2 and may be in contact with the semiconductor layer 201. The first source pattern SC1 may include a semiconductor pattern doped with impurities, for example, polysilicon doped with impurities of a first conductivity type. The second source pattern SC2 may include a semiconductor pattern doped with impurities, for example, polysilicon doped with impurities. The second source pattern SC2 may further include a semiconductor material different from that of the first source pattern SC1. A conductivity type of the impurity doped into the second source pattern SC2 may be the same as a conductivity type of the impurity doped into the first source pattern SC1. A concentration of impurities doped in the second source pattern SC2 may be the same as or different from a concentration of impurities doped in the first source pattern SC1.

The inter-electrode insulating layers 12, 22, and 24 and the electrode layers EL1 and EL2 may be penetrated by cell vertical patterns VS. The cell vertical patterns VS may be disposed on the cell region CAR. A gate insulating layer GO may be interposed between the electrode layers EL1 and EL2 and the cell vertical patterns VS. Each of the cell vertical patterns VS may have a hollow cup shape. The cell vertical patterns VS may include, for example, a silicon single crystal layer or polysilicon that is not doped with impurities. The sidewalls of the cell vertical patterns VS may have an inflection point adjacent to the first stacked structure STC1 and the second stacked structure STC2.

An interior of the cell vertical patterns VS may be filled with buried insulating patterns 29. For example, the buried insulating pattern 29 may have a single-layer or multi-layer structure of at least one of a silicon oxide layer, a silicon nitride layer, and a silicon oxynitride layer. A bit line pad BPD may be disposed on each of the cell vertical patterns VS. The bit line pad BPD may include polysilicon doped with impurities, or metal such as tungsten, aluminum, and copper. The second source pattern SC2 may penetrate the gate insulating layer GO and may be in contact with lower sidewalls of the cell vertical patterns VS, respectively.

FIG. 15 is an enlarged view of portion ‘P4’ of FIG. 14.

Referring to FIGS. 14 and 15, the gate insulating layer GO may include a tunnel insulating layer TL, a charge storage layer SN, and a blocking insulating layer BCL. The charge storage layer SN may include at least one of a trap insulating layer, a floating gate electrode, or an insulating layer including conductive nano dots. Specifically, the charge storage layer SN includes at least one of a silicon nitride layer, a silicon oxynitride layer, a silicon-rich nitride layer, nanocrystalline silicon, and a laminated trap layer. The tunnel insulating layer TL may include a material having a larger band gap than a material of the charge storage layer SN, and the blocking insulating layer BCL may be a high dielectric layer such as an aluminum oxide layer or a hafnium oxide layer.

The gate insulating layer GO may further include a high dielectric layer HL. The high dielectric layer HL may be interposed between the blocking insulating layer BCL and the electrode layers EL1 and EL2. The high dielectric layer HL may be interposed between the electrode layers EL1 and EL2 and the inter-electrode insulating layers 12, 22, and 24. The high dielectric layer HL may have a higher dielectric constant than a silicon oxide layer and may include, for example, a metal oxide layer such as a hafnium oxide layer or an aluminum oxide layer. The second source pattern SC2 may penetrate the gate insulating layer GO and contact the cell vertical patterns VS. A lower portion of the gate insulating layer GO may be separated from an upper portion of the gate insulating layer GO by the second source pattern SC2.

On the connection region CNR, the lower insulating patterns 5 may penetrate the source structure SCL and the semiconductor layer 201 and may be in contact with the interface layer 111. The lower insulating patterns 5 may be formed of, for example, silicon oxide.

A second upper insulating layer 207 may be disposed on the first upper insulating layer 205. First conductive lines BLL extending in the second direction D2 and parallel to each other may be disposed on the second upper insulating layer 207. In the cell region CAR, the first contacts CT1 penetrate the first and second upper insulating layers 205 and 207 to be connected to at least one of the bit line pads BPD and the first conductive lines BLL.

The third contacts CT3 penetrate the second upper insulating layer 207. One of the third contacts CT3 may be in contact with the first through via TV1. The stacked structures STC1 and STC2 may have a step shape in the connection region CNR. That is, the electrode layers EL1 and EL2 and the inter-electrode insulating layers 12, 22, and 24 may have a step shape in the connection region CNR. As the electrode layers EL1 and EL2 and the inter-electrode insulating layers 12, 22, and 24 approach the peripheral circuit structure PS, the electrode layers EL1 and EL2 and the inter-electrode insulating layers 12, 22, and 24 may extend and protrude in the first direction D1. Ends of the first stacked structures STC1 in the connection region CNR may be covered with a first flat insulating layer 210. Ends of the second stacked structures STC2 in the connection region CNR may be covered with a second flat insulating layer 220. The flat insulating layers 210 and 220 may include a silicon oxide layer or a porous insulating layer.

Ends of the electrode layers EL1 and EL2 may be connected to cell contact plugs CC, respectively. The cell contact plugs CC may penetrate the first upper insulating layer 205 and the inter-electrode insulating layers 12, 22, and 24 and be in contact with corresponding ones of the electrode layers EL1 and EL2, respectively. One of the cell contact plugs CC may be in contact with one of the electrode layers EL1 and EL2, and a side surface of the one cell contact plug CC may protrude laterally at a level of the one electrode layer EL1 and EL2. A contact insulating layer 4 may be interposed between the one cell contact plug CC and other electrode layers EL1 and EL2 that are not connected to the one cell contact plug CC. The second contact CT2 may be connected to the cell contact plugs CC. Connection wirings CL may be disposed on the second upper insulating layer 207.

In the connection region CNR, the first through via TV1 may be in contact with the first landing wiring LT1 through the first upper insulating layer 205, the flat insulating layers 210 and 220, the semiconductor layer 201, and the interface layer 111. A mark pattern IP is disposed in the first landing wiring LT1. The first through via TV1 may be spaced apart from the stacked structures STC1 and STC2. The first through via TV1 may be connected to the connection wiring CL through a second contact CT2 and a third contact CT3 disposed in the second upper insulating layer 207, respectively. Accordingly, the electrode layers EL1 and EL2 may be connected to, for example, a decoder circuit of the peripheral circuit structure PS. A sidewall of the first through via TV1 may be surrounded by a first via insulating layer 11.

The first through via TV1 may include at least one metal selected from tungsten, aluminum, copper, titanium, and tantalum. The first via insulating layer 11 may include an insulating material such as a silicon oxide layer, a silicon nitride layer, or a silicon oxynitride layer. The cell contact plugs CC and the first through via TV1 may have the same height.

A ground region WR may be disposed in the semiconductor layer 201 at a distance from the first through via TV1. The ground region WR may be doped with an impurity of the first conductivity type doped in the semiconductor layer 201 at a higher concentration than the concentration of the impurity doped in the semiconductor layer 201. In the connection region CNR, the ground contact plug WC may be in contact with the ground region WR through the first upper insulating layer 205 and the flat insulating layers 210 and 220.

The connection wirings CL may be covered with a third upper insulating layer 209. The third upper insulating layer 209 may be penetrated by the fourth contact CT4. A fourth upper insulating layer 211 is disposed on the third upper insulating layer 209.

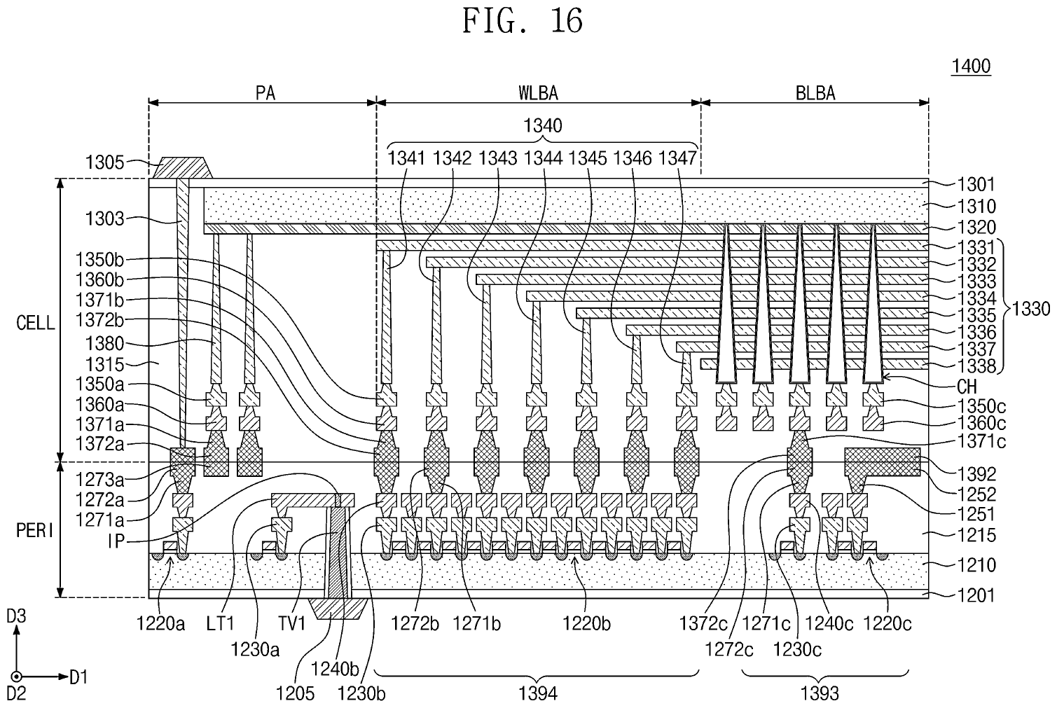

FIG. 16 is a cross-sectional view of a semiconductor memory device according to embodiments of the present disclosure.

Referring to FIG. 16, a memory device 1400 may have a chip to chip (C2C) structure. The C2C structure may connect an upper chip to a lower chip through a boding manner after forming the upper chip including a cell array structure CELL on a first wafer and forming the lower chip including a peripheral circuit structure PERI on a second wafer different from the first wafer. For example, the bonding manner may refer to a technique for electrically connecting a bonding metal formed on the uppermost metal layer of the upper chip and a bonding metal formed on the uppermost metal layer of the lower chip. For example, when the bonding metal is formed of copper (Cu), the bonding manner may be a Cu-to-Cu bonding manner, and the bonding metal may be formed of aluminum (Al) or tungsten (W).

Each of the peripheral circuit structure PERI and the cell array structure CELL of the memory device 1400 may include an external pad bonding region PA, a word line bonding region WLBA, and a bit line bonding region BLBA.

The peripheral circuit structure PERI may include a first substrate 1210, an interlayer insulating layer 1215, a plurality of circuit elements 1220a, 1220b, and 1220c formed on the first substrate 1210, first metal layers 1230a, 1230b, 1230c connected to each of the plurality of circuit elements 1220a, 1220b, and 1220c, and second metal layers LT1, 1240b, and 1240c formed on the first meatal layers 1230a, 1230b, and 1230c. In one embodiment, the first metal layers 1230a, 1230b, and 1230c may be formed of tungsten, which has a relatively high electrical resistivity. The second metal layers LT1, 1240b, and 1240c may be formed of copper with relatively low electrical resistivity.

In the present disclosure, only the first metal layers 1230a, 1230b, and 1230c and the second metal layers LT1, 1240b, and 1240c are shown and described, but embodiments of the present disclosure are not limited thereto, and at least one additional metal layer may be formed on the second metal layers LT1, 1240b, and 1240c. At least a portion of the one or more metal layers formed on the second metal layer LT1, 1240b, and 1240c may be formed of aluminum, which has a lower electrical resistivity than the copper forming the second metal layer LT1, 1240b, and 1240c. The second metal layers LT1, 1240b, and 1240c include the first landing wiring LT1. A mark pattern IP is disposed in the first landing wiring LT1.

The interlayer insulating layer 1215 may be disposed on the first substrate 1210 to cover the plurality of circuit elements 1220a, 1220b, and 1220c, the first metal layer 1230a, 1230b, and 1230c, and the second metal layer LT1, 1240b, and 1240c, and may include an insulating material such as silicon oxide, silicon nitride, etc.

Lower bonding metals 1271b and 1272b may be formed on the second metal layer 1240b of the word line bonding region WLBA. In the word line bonding region WLBA, the lower bonding metals 1271b and 1272b of the peripheral circuit structure PERI may be electrically connected to the upper bonding metals 1371b and 1372b of the cell array structure CELL by a bonding manner. The lower bonding metals 1271b and 1272b and the upper bonding metals 1371b and 1372b may be formed of aluminum, copper, or tungsten. The upper bonding metals 1371b and 1372b may also be referred to as upper bonding pads. The lower bonding metals 1271b and 1272b may also be referred to as lower bonding pads.

The cell array structure CELL may correspond to the cell array structure CS described with reference to FIG. 14. The cell array structure CELL may provide at least one memory block. The cell array structure CELL may include a second substrate 1310 and a common source line 1320. On the second substrate 1310, a plurality of word lines 1331 to 1338 (collectively referred to as 1330) may be stacked in a direction perpendicular to the upper surface of the second substrate 1310, along the Z-axis direction. String selection lines and a ground selection line may be disposed above and below the word lines 1330, respectively, and a plurality of word lines 1330 may be disposed between the string selection lines and the ground selection line.

In the bit line bonding region BLBA, the channel structure 1CH may extend in a direction perpendicular to the upper surface of the second substrate 1310 (i.e., Z-axis direction) to penetrate the word lines 1330, the string selection lines, and the ground selection line. A channel structure CH may include a data storage layer, a channel layer, and a buried insulating layer, and the channel layer may be electrically connected to the first metal layer 1350c and the second metal layer 1360c. For example, the first metal layer 1350c may be a bit line contact, and the second metal layer 1360c may be a bit line. In one embodiment, the bit line 1360c may extend in a first direction (i.e., Y-axis direction) parallel to the upper surface of the second substrate 1310.

In one embodiment shown in FIG. 16, a region where the channel structure CH and the bit line 1360c are placed may be defined as the bit line bonding region BLBA. The bit line 1360c may be electrically connected to the circuit elements 1220c that provide the page buffer 1393 in the peripheral circuit structure PERI in the bit line bonding region BLBA. For example, the bit line 1360c may be connected to the upper bonding metals 1371c and 1372c in the peripheral circuit structure PERI, and the upper bonding metals 1371c and 1372c may be connected to lower bonding metals 1271c and 1272c of the page buffer 1393.

In the word line bonding region WLBA, the word lines 1330 may extend in a second direction (i.e., X-axis direction) perpendicular to the first direction and parallel to the upper surface of the second substrate 1310, and may connected to a plurality of cell contact plugs 1341 to 1347 (collectively referred to as 1340). The shape of the cell contact plugs 1341 to 1347 (1340) may be the same as the cell contacts CC of FIG. 14.

The word lines 1330 and the cell contact plugs 1340 may be connected to each other at pads provided by at least some of the word lines 1330 extending to different lengths in the second direction. A first metal layer 1350b and a second metal layer 1360b may be sequentially connected to the top of the cell contact plugs 1340 connected to the word lines 1330. The cell contact plugs 1340 may be connected to the cell peripheral circuit structure PERI through the upper bonding metals 1371b and 1372b of the cell region CELL and the lower bonding metals 1271b and 1272b of the peripheral circuit structure PERI in the word line bonding region WLBA.

The cell contact plugs 1340 may be electrically connected to circuit elements 1220b forming the row decoder 1394 in the peripheral circuit structure PERI. In one embodiment, an operation voltage of the circuit elements 1220b forming the row decoder 1394 may be different from an operation voltage of the circuit elements 1220c forming the page buffer 1393. For example, an operation voltage of the circuit elements 1220c forming the page buffer 1393 may be greater than the operation voltage of the circuit elements 1220b forming the row decoder 1394.

A common source line contact plug 1380 may be disposed in an external pad bonding region PA. The common source line contact plug 1380 may be formed of a conductive material such as metal, metal compound, or polysilicon, and may be electrically connected to the common source line 1320. A first metal layer 1350a and a second metal layer 1360a may be sequentially stacked on the common source line contact plug 1380. For example, a region where the common source line contact plug 1380, the first metal layer 1350a, and the second metal layer 1360a are disposed may be defined as the external pad bonding region PA.

Meanwhile, input/output pads 1205 and 1305 may be disposed in the external pad bonding region PA. Referring to FIG. 16, a lower insulating layer 1201 may be formed on the lower portion of the first substrate 1210 to cover the lower surface of the first substrate 1210, and a first input/output pad 1205 may be formed on the lower insulating layer 1201. The first input/output pad 1205 may be connected to at least one of the plurality of circuit elements 1220a, 220b, and 220c disposed in the peripheral circuit structure PERI through the first through via TV1, and may be separated from the first substrate 1210 by the lower insulating layer 1201. Additionally, a side insulating layer is disposed between the first through via TV1 and the first substrate 1210 to electrically separate the first through via TV1 from the first substrate 1210.

Referring to FIG. 16, an upper insulating layer 1301 may be formed on the second substrate 1310 to cover the upper surface of the second substrate 1310, and a second input/output pad 1305 may be disposed on the upper insulating layer 1301. The second input/output pad 1305 may be connected to at least one of the plurality of circuit elements 1220a, 1220b, and 1220c disposed in the peripheral circuit structure PERI through the second input/output contact plug 1303. In one embodiment, the second input/output pad 1305 may be electrically connected to the circuit element 1220a.

According to embodiments, the second substrate 1310 and the common source line 1320 may not be disposed in the region where the second input/output contact plug 1303 is disposed. Additionally, the second input/output pad 1305 may not overlap the word lines 1380 in the third direction (i.e., Z-axis direction). Referring to FIG. 16, the second input/output contact plug 1303 may be separated from the second substrate 1310 in a direction parallel to the upper surface of the second substrate 1310, and the interlayer insulating layer 1315 of the cell array structure CELL may be connected to the second input/output pad 1305.

According to embodiments, the first input/output pad 1205 and the second input/output pad 1305 may be formed selectively. For example, the memory device 1400 may include only the first input/output pad 1205 disposed on the upper surface of the first substrate 1210, or may include only the second input/output pad 1305 disposed on the upper surface of the second substrate 1310. Alternatively, the memory device 1400 may include both the first input/output pad 1205 and the second input/output pad 1305.

In the external pad bonding region PA and bit line bonding region BLBA included in each of the cell array structure CELL and the peripheral circuit region PERI, a metal pattern of the uppermost metal layer may exist as a dummy pattern, or the uppermost metal layer may be empty.

The memory device 1400 may form a lower metal pattern 1273a having the same shape as the upper metal pattern 1372a of the cell array structure CELL on the uppermost metal layer of the peripheral circuit structure PERI, corresponding to the upper metal pattern 1372a formed on the uppermost metal layer of the cell array structure CELL in the external pad bonding region PA. The lower metal pattern 1273a formed on the uppermost metal layer of the peripheral circuit structure PERI may not be connected to a separate contact in the peripheral circuit structure PERI. Similarly, an upper metal pattern 1372a having the same shape as the lower metal pattern 1273a of the peripheral circuit structure PERI, corresponding to the lower metal pattern 1273a formed on the uppermost metal layer of the peripheral circuit structure PERI in the external pad bonding region PA, may be formed on the upper metal layer of the cell array structure CELL.

Lower bonding metals 1271b and 1272b may be formed on the second metal layer 1240b of the word line bonding region WLBA. In the word line bonding region WLBA, the lower bonding metals 1271b and 1272b of the peripheral circuit structure PERI may be electrically connected to the upper bonding metals 1371b and 1372b of the cell array structure CELL by a bonding manner.

Additionally, corresponding to the lower metal pattern 1252 formed on the uppermost metal layer of the peripheral circuit structure PERI, an upper metal pattern 1392 having the same shape as the lower metal pattern 1252 of the peripheral circuit structure PERI may be formed on the uppermost metal layer of the cell array structure CELL in the bit line bonding region BLBA. A contact may not be formed on the upper metal pattern 1392 formed on the uppermost metal layer of the cell array structure CELL.

In the image sensor and semiconductor device according to embodiments of the present disclosure, because the landing wiring includes the mark pattern in contact with the through via, when forming the through via hole for the through via, it is possible to verify whether the via hole is properly open by checking if the mark pattern is exposed or not. Accordingly, defects related to the through via holes not being open may be prevented, thereby improving the reliability of the image sensor and the semiconductor device.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art. The embodiments of FIGS. 3 to 16 may be combined with each other.

1. An image sensor comprising:
a first semiconductor chip comprising:
a first substrate;
a first interlayer insulating layer covering the first substrate; and
first wirings and a first landing wiring disposed in the first interlayer insulating layer;
a first through via penetrating the first substrate and contacting the first landing wiring; and
at least one first mark pattern disposed in the first landing wiring and overlapping the first through via.

2. The image sensor of claim 1, wherein the at least one first mark pattern is in contact with the first through via.

3. The image sensor of claim 1, wherein a portion of the first through via is inserted into the first landing wiring and is in contact with an inner sidewall of the first landing wiring.

4. The image sensor of claim 1, further comprising:
a second semiconductor chip disposed on the first semiconductor chip and comprising:
a second substrate comprising a plurality of light-receiving regions;
a second interlayer insulating layer covering the second substrate; and
second wirings disposed in the second interlayer insulating layer,
wherein the first semiconductor chip further comprises a first lower insulating layer covering a lower surface of the first substrate, and a first bonding pad disposed in the first lower insulating layer and contacting the first through via,
wherein the image sensor further comprises a third semiconductor chip disposed below the first semiconductor chip, and
wherein the third semiconductor chip comprises a third substrate, a third interlayer insulating layer covering the third substrate and contacting the first lower insulating layer, third wirings disposed in the third interlayer insulating layer, and a second bonding pad on an upper end of the third interlayer insulating layer and contacting the first bonding pad.

5. The image sensor of claim 1, further comprising:
a second semiconductor chip disposed on the first semiconductor chip and comprising:
a second substrate comprising a plurality of light-receiving regions;
a second interlayer insulating layer covering the second substrate; and
second wirings disposed in the second interlayer insulating layer,
wherein the second interlayer insulating layer is disposed below the second substrate and is in contact with an upper surface of the first interlayer insulating layer,
wherein the second semiconductor chip further comprises a transfer gate disposed on a lower surface of the second substrate in at least one of the plurality of light-receiving regions, and a floating diffusion region disposed in the second substrate next to the transfer gate,
wherein the first semiconductor chip further comprises a source follower gate disposed on the first substrate, and
wherein the first wirings and the second wirings connect the floating diffusion region to the source follower gate.

6. The image sensor of claim 1, further comprising:
a second semiconductor chip disposed on the first semiconductor chip and comprising:
a second substrate comprising a plurality of light-receiving regions;
a second interlayer insulating layer covering the second substrate; and
second wirings disposed in the second interlayer insulating layer,
wherein the first semiconductor chip further comprises a second landing wiring disposed in the first interlayer insulating layer and spaced apart from the first landing wiring,
wherein the second interlayer insulating layer is disposed below the second substrate and is in contact with an upper surface of the first interlayer insulating layer,
wherein the second substrate comprises a main region and an edge region,
wherein the second semiconductor chip further comprises:
a deep separation portion disposed in the second substrate and separating the plurality of light-receiving regions;
a color filter array disposed on the second substrate; and
a microlens array disposed on the color filter array, and
wherein the image sensor further comprises:
a second through via that penetrates the second substrate, the second interlayer insulating layer, and a portion of the first interlayer insulating layer to be in contact with the second landing wiring in the edge region; and
at least one second mark pattern disposed in the second landing wiring.

7. The image sensor of claim 6, wherein the deep separation portion comprises:
a separation conductive pattern; and
a separation insulating layer interposed between the separation conductive pattern and the second substrate, wherein the second semiconductor chip further comprises:
a back contact pattern penetrating a portion of the second substrate and a portion of the deep separation portion to be in contact with the separation conductive pattern in the edge region; and
a back wiring disposed on the second substrate and connecting the back contact pattern to the second through via.

8. The image sensor of claim 1, further comprising:
a second semiconductor chip disposed on the first semiconductor chip and comprising:
a second substrate comprising a plurality of light-receiving regions;
a second interlayer insulating layer covering the second substrate; and
second wirings disposed in the second interlayer insulating layer,
wherein the second interlayer insulating layer is disposed below the second substrate,
wherein the first semiconductor chip further comprises:
an upper insulating layer disposed on the first substrate and contacting a lower surface of the second interlayer insulating layer;
a source follower gate disposed below the first substrate; and
a first bonding pad disposed on an upper end of the upper insulating layer and connected to the first through via, and
wherein the second semiconductor chip further comprises a second bonding pad disposed below the second interlayer insulating layer and contacting the first bonding pad.

9. The image sensor of claim 1, wherein the at least one first mark pattern comprises a material different from a material of the first landing wiring.

10. An image sensor comprising:
a first semiconductor chip comprising a first substrate, a first interlayer insulating layer covering the first substrate, and first wirings and a first landing wiring disposed in the first interlayer insulating layer;
a second semiconductor chip disposed on the first semiconductor chip and comprising:
a second substrate comprising a plurality of light-receiving regions;
a second interlayer insulating layer covering the second substrate; and
second wirings disposed in the second interlayer insulating layer; and
a first through via penetrating the first substrate and contacting the first landing wiring,
wherein the first landing wiring comprises a pad portion in contact with the first through via,
wherein the pad portion has a cross shape or line shape when viewed in a plan view, and
wherein the first through via covers both an upper surface and a side surface of the pad portion.

11. The image sensor of claim 10, wherein the at least one first mark pattern is in contact with the first through via, and
wherein a portion of the first through via is inserted into the first landing wiring and contacts an inner sidewall of the first landing wiring.

12. The image sensor of claim 10, wherein the first semiconductor chip further comprises a first lower insulating layer covering a lower surface of the first substrate, and a first bonding pad disposed in the first lower insulating layer and contacting the first through via,
wherein the image sensor further comprises a third semiconductor chip disposed below the first semiconductor chip, and
wherein the third semiconductor chip comprises a third substrate, a third interlayer insulating layer covering the third substrate and contacting the first lower insulating layer, third wirings disposed in the third interlayer insulating layer, and a second bonding pad disposed on an upper end of the third interlayer insulating layer and contacting the first bonding pad.

13. The image sensor of claim 10, wherein the second interlayer insulating layer is disposed below the second substrate and is in contact with an upper surface of the first interlayer insulating layer,
wherein the second semiconductor chip further comprises a transfer gate disposed on a lower surface of the second substrate in each of the plurality of light-receiving regions, and a floating diffusion region disposed in the second substrate next to the transfer gate,
wherein the first semiconductor chip further comprises a source follower gate disposed on the first substrate, and
wherein the first wirings and the second wirings connect the floating diffusion region to the source follower gate.

14. The image sensor of claim 10, wherein the first semiconductor chip further comprises a second landing wiring spaced apart from a first landing wiring,
wherein the second interlayer insulating layer is disposed below the second substrate and is in contact with an upper surface of the first interlayer insulating layer,
wherein the second substrate comprises a main region and an edge region,
wherein the second semiconductor chip further comprises:
a deep separation portion disposed in the second substrate and separating the light-receiving regions;
a color filter array disposed on the second substrate; and
a microlens array disposed on the color filter array, and
wherein the image sensor further comprises:
a second through via that penetrates the second substrate, the second interlayer insulating layer, and a portion of the first interlayer insulating layer to be in contact with the second landing wiring in the edge region; and
at least one second mark pattern disposed in the second landing wiring.

15. The image sensor of claim 14, wherein the deep separation portion comprises:
a separation conductive pattern; and
a separation insulating layer interposed between the separation conductive pattern and the second substrate,
wherein the second semiconductor chip further comprises:
a back contact pattern penetrating a portion of the second substrate and a portion of the deep separation portion to be in contact with the separation conductive pattern in the edge region; and
a back wiring disposed on the second substrate and connecting the back contact pattern to the second through via.

16. The image sensor of claim 10, wherein the second interlayer insulating layer is disposed below the second substrate,
wherein the first semiconductor chip further comprises:
an upper insulating layer disposed on the first substrate and contacting a lower surface of the second interlayer insulating layer;
a source follower gate disposed below the first substrate; and
a first bonding pad disposed on an upper end of the upper insulating layer and connected to the first through via,
wherein the second semiconductor chip further comprises a second bonding pad disposed below the second interlayer insulating layer and contacting the first bonding pad.

17. A semiconductor device comprising:
a first semiconductor chip comprising a first substrate, a first interlayer insulating layer covering the first substrate, and first wirings and a first landing wiring disposed in the first interlayer insulating layer;
a first through via penetrating the first substrate and contacting the first landing wiring; and
at least one first mark pattern disposed in the first landing wiring and overlapping the first through via.

18. The semiconductor device of claim 17, wherein a portion of the first through via is inserted into the first landing wiring and contacts an inner sidewall of the first landing wiring.

19. The semiconductor device of claim 17, further comprising:
a second semiconductor chip comprising a second substrate, a second interlayer insulating layer covering the second substrate, and second wirings disposed in the second interlayer insulating layer, the second semiconductor chip disposed on the first semiconductor chip,
wherein the first interlayer insulating layer covers an upper surface of the first substrate,
wherein the second interlayer insulating layer covers a lower surface of the second substrate,
wherein the first semiconductor chip further comprises a first bonding pad disposed on an upper end of the first interlayer insulating layer,
wherein the second semiconductor chip further comprises a second bonding pad disposed below the second interlayer insulating layer and contacting the first bonding pad.

20. The semiconductor device of claim 17, further comprising:
a second semiconductor chip comprising a second substrate, a second interlayer insulating layer covering the second substrate, and second wirings disposed in the second interlayer insulating layer, the second semiconductor chip disposed on the first semiconductor chip, and electrode layers disposed below the second substrate and vertical patterns penetrating the electrode layers, and
wherein the first semiconductor chip further comprises a plurality of transistors electrically connected to the electrode layers.

21. (canceled)
